(19) United States
(12) Patent Application Publication
(10) Pub. No.: US 2010/0314715 A1
(43) Pub. Date: Dec. 16, 2010

(54) SEMICONDUCTOR DEVICE AND METHOD OF MANUFACTURING THE SAME

(75) Inventor: Shun Fujimoto, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/813,108

(22) Filed: Jun. 10, 2010

(30) Foreign Application Priority Data
Jun. 11, 2009 (JP) P2009-140068

(51) Int. Cl. H01L 27/08

(52) U.S. Cl. 257/532; 257/E27.048

(57) ABSTRACT

A semiconductor device includes a memory cell area; and a peripheral circuit area separated by a groove from the memory cell area. The peripheral circuit area is positioned outside the memory cell area. The memory cell area includes a plurality of electrodes that stand; and a first insulating film that support the plurality of electrodes standing. The first insulating film has a plurality of holes through which the plurality of electrodes penetrates. The first insulating film is in contact with at least a part of an outside surface of the electrode. The first insulating film has at least a first opening which is connected to part of the plurality of holes. The first insulating film has at least a second opening which is closer to the groove than any holes of the plurality of holes. The second opening is separated from the plurality of holes.

### BACKGROUND OF THE INVENTION

1. Field of the Invention

The present invention relates to a semiconductor device and a method of manufacturing a semiconductor device. More particularly, the present invention relates to a method of manufacturing a semiconductor device, which includes a process of exposing an outer wall of a bottom electrode of a capacitor using wet etching, and a semiconductor device manufactured by this method.

Priority is claimed on Japanese Patent Application No. 2009-140068, filed Jun. 11, 2009, the content of which is incorporated herein by reference.

2. Description of the Related Art

As semiconductor devices become shrunken, a memory cell area for a DRAM (Dynamic Random Access Memory) device becomes also decreased. In order to ensure a sufficient capacitance for a capacitor which forms a memory cell, the capacitor is formed three-dimensionally. Specifically, the surface area of the capacitor can be increased by forming a bottom electrode of the capacitor in a cylindrical shape or a pillar shape and using a side wall of the bottom electrode as a capacitor. As the area of a memory cell decreases, the area of the bottom portion of the bottom electrode of a capacitor also decreases. For this reason, in the manufacturing process where an outer wall of the bottom electrode of the capacitor is exposed using wet etching process, the bottom electrode is likely to be collapsed or fallen, thereby forming short-circuit to an adjacent bottom electrode. Japanese Unexamined Patent Application, First Publications, Nos. JP-A-2003-297952 and JP-A-2008-193088 each address that a support film serving as a support is disposed between bottom electrodes in order to prevent the collapse of the electrode.

### SUMMARY

In one embodiment, a semiconductor device may include, but is not limited to, a memory cell area; and a peripheral circuit area separated by a groove from the memory cell area; the peripheral circuit area being positioned outside the memory cell area. The memory cell area may include, but is not limited to, a plurality of electrodes that stand; and a first insulating film that support the plurality of electrodes standing. The first insulating film has a plurality of holes through which the plurality of electrodes penetrates. The first insulating film is in contact with at least a part of an outside surface of the electrode. The first insulating film has at least a first opening which is connected to part of the plurality of holes. The first insulating film has at least a second opening which is closer to the groove than any holes of the plurality of holes. The second opening is separated from the plurality of holes.

In one embodiment, a semiconductor device may include, but is not limited to, a memory cell area; and a peripheral circuit area separated by a groove from the memory cell area; the peripheral circuit area being positioned outside the memory cell area. The memory cell area may include, but is not limited to, a plurality of electrodes that stand; and a first insulating film filling an inner space defined by an inner wall of each of the plurality of electrodes. The first insulating film supports the plurality of electrodes standing. The first insulating film may have at least a first opening that includes part of the plurality of electrodes. The first insulating film may have at least a second opening which is closer to the groove than any electrodes of the plurality of electrodes. The second opening includes none of the plurality of electrodes.

In still another embodiment, a semiconductor device may include, but is not limited to, a memory cell area; and a peripheral circuit area separated by a groove from the memory cell area. The peripheral circuit area is positioned outside the memory cell area. The memory cell area may include, but is not limited to, a plurality of first electrodes that stand; and a first insulating film being in contact with at least a part of an outside surface of the first electrode. The first insulating film supports the plurality of first electrodes standing. The first insulating film may have at least a first opening that includes part of the plurality of first electrodes. The first insulating film may have at least a second opening which is closer to the groove than any first electrodes of the plurality of first electrodes. The second opening includes none of the plurality of first electrodes. The second opening is separated from the first opening. The memory cell area may include, but is not limited to, a plurality of second electrodes that are connected to the plurality of first electrodes. The plurality of second electrodes is positioned over the plurality of first electrodes. The memory cell area may include, but is not limited to, a second insulating film being in contact with at least a part of an outside surface of the second electrode. The second insulating film supports the plurality of second electrodes standing. The second insulating film may have at least a third opening that includes part of the plurality of second electrodes. The second insulating film may have at least a fourth opening which is closer to the groove than any second electrodes of the plurality of second electrodes. The fourth opening includes none of the plurality of second electrodes. The fourth opening is separated from the third opening.

In yet another embodiment, a method of forming a semiconductor device may include, but is not limited to, the following processes. Contact pads are formed over a semiconductor substrate. A first interlayer insulating film is formed which covers the contact pads. A first insulating film is formed over the first interlayer insulating film. First holes are formed which penetrate the first insulating film and the first interlayer insulating film. The first holes reach the contact pads. First electrodes are formed in contact with inner walls of the first holes and with the contact pads. First and second openings are formed simultaneously in the first insulating film. The first opening is connected to part of the first holes. The second opening is positioned in a peripheral region outside a memory cell area. The second opening is separated from any of the first holes. The first interlayer insulating film is removed to expose outer surfaces of the first electrodes.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a conceptual view showing a DRAM device (semiconductor chip) including a semiconductor device according to the embodiment of the invention;

FIG. 2 is a plan view showing a semiconductor device according to the first embodiment of the invention;

FIG. 3 is a conceptual plan view showing the planar structure of each memory cell in detail;

FIG. 4A is a fragmentary cross sectional elevation view taken along the line A-A′ of FIG. 2 and FIG. 3;

FIG. 4B is a fragmentary cross sectional elevation view taken along the line B-B′ of FIG. 2;

FIG. 5A is a cross sectional elevation view illustrating a semiconductor device in a step involved in a method of forming the semiconductor device, taken along an A-A′ line of FIGS. 2 and 3;

FIG. 5B is a cross sectional elevation view illustrating a semiconductor device in the step of FIG. 5A involved in the method of forming the semiconductor device, taken along a B-B′ line of FIGS. 2 and 3;

FIG. 6A is a cross sectional elevation view illustrating a semiconductor device in a step, subsequent to the step of FIGS. 5A and 5B, involved in a method of forming the semiconductor device, taken along an A-A′ line of FIGS. 2 and 3;

FIG. 6B is a cross sectional elevation view illustrating a semiconductor device in the step of FIG. 6A involved in the method of forming the semiconductor device, taken along a B-B′ line of FIGS. 2 and 3;

FIG. 7A is a cross sectional elevation view illustrating a semiconductor device in a step, subsequent to the step of FIGS. 6A and 6B, involved in a method of forming the semiconductor device, taken along an A-A′ line of FIGS. 2 and 3;

FIG. 7B is a cross sectional elevation view illustrating a semiconductor device in the step of FIG. 7A involved in the method of forming the semiconductor device, taken along a B-B′ line of FIGS. 2 and 3;

FIG. 8A is a cross sectional elevation view illustrating a semiconductor device in a step, subsequent to the step of FIGS. 7A and 7B, involved in a method of forming the semiconductor device, taken along an A-A′ line of FIGS. 2 and 3;

FIG. 8B is a cross sectional elevation view illustrating a semiconductor device in the step of FIG. 8A involved in the method of forming the semiconductor device, taken along a B-B′ line of FIGS. 2 and 3;

FIG. 9A is a cross sectional elevation view illustrating a semiconductor device in a step, subsequent to the step of FIGS. 8A and 8B, involved in a method of forming the semiconductor device, taken along an A-A′ line of FIGS. 2 and 3;

FIG. 9B is a cross sectional elevation view illustrating a semiconductor device in the step of FIG. 9A involved in the method of forming the semiconductor device, taken along a B-B′ line of FIGS. 2 and 3;

FIG. 10A is a cross sectional elevation view illustrating a semiconductor device in a step, subsequent to the step of FIGS. 9A and 9B, involved in a method of forming the semiconductor device, taken along an A-A′ line of FIGS. 2 and 3;

FIG. 10B is a cross sectional elevation view illustrating a semiconductor device in the step of FIG. 10A involved in the method of forming the semiconductor device, taken along a B-B′ line of FIGS. 2 and 3;

FIG. 11A is a cross sectional elevation view illustrating a semiconductor device in a step, subsequent to the step of FIGS. 10A and 10B, involved in a method of forming the semiconductor device, taken along an A-A′ line of FIGS. 2 and 3;

FIG. 11B is a cross sectional elevation view illustrating a semiconductor device in the step of FIG. 11A involved in the method of forming the semiconductor device, taken along a B-B′ line of FIGS. 2 and 3;

FIG. 12A is a cross sectional elevation view illustrating a semiconductor device in a step, subsequent to the step of FIGS. 11A and 11B, involved in a method of forming the semiconductor device, taken along an A-A′ line of FIGS. 2 and 3;

FIG. 12B is a cross sectional elevation view illustrating a semiconductor device in the step of FIG. 12A involved in the method of forming the semiconductor device, taken along a B-B′ line of FIGS. 2 and 3;

FIG. 13A is a cross sectional elevation view illustrating a semiconductor device in a step, subsequent to the step of FIGS. 12A and 12B, involved in a method of forming the semiconductor device, taken along an A-A′ line of FIGS. 2 and 3; FIG. 13B is a cross sectional elevation view illustrating a semiconductor device in the step of FIG. 13A involved in the method of forming the semiconductor device, taken along a B-B′ line of FIGS. 2 and 3;

FIG. 14 is a plan view showing arrays of capacitor elements;

FIG. 15 shows an example of the arrangement relationship between a semiconductor substrate and a chemical bath for a wet etching process

FIG. 16 shows a sectional view taken along the line C-C′ of FIG. 2 in a state where the wet etching process is terminated and the semiconductor wafer is picked up from the chemical bath;

FIG. 17 is a plan view showing a semiconductor device according to a modification to the first embodiment of the invention;

FIG. 18 is a plan view showing a semiconductor device according to another modification to the first embodiment of the invention;

FIG. 19 is a plan view showing a semiconductor device according to still another modification to the first embodiment of the invention;

FIG. 20A is a cross sectional elevation view illustrating a semiconductor device in a step involved in a method of forming the semiconductor device, taken along an A-A′ line of FIG. 2;

FIG. 20B is a cross sectional elevation view illustrating a semiconductor device in the step of FIG. 20A involved in the method of forming the semiconductor device, taken along a B-B′ line of FIGS. 2 and 3;

FIG. 21A is a cross sectional elevation view illustrating a semiconductor device in a step, subsequent to the step of FIGS. 20A and 2013, involved in a method of forming the semiconductor device, taken along an A-A′ line of FIG. 2;

FIG. 21B is a cross sectional elevation view illustrating a semiconductor device in the step of FIG. 21A involved in the method of forming the semiconductor device, taken along a B-B′ line of FIGS. 2 and 3;

FIG. 22A is a cross sectional elevation view illustrating a semiconductor device in a step, subsequent to the step of FIGS. 21A and 21B, involved in a method of forming the semiconductor device, taken along an A-A′ line of FIG. 2;

FIG. 22B is a cross sectional elevation view illustrating a semiconductor device in the step of FIG. 22A involved in the method of forming the semiconductor device, taken along a B-B′ line of FIGS. 2 and 3;

FIG. 23A is a cross sectional elevation view illustrating a semiconductor device in a step, subsequent to the step of FIGS. 22A and 22B, involved in a method of forming the semiconductor device, taken along an A-A′ line of FIG. 2;

FIG. 23B is a cross sectional elevation view illustrating a semiconductor device in the step of FIG. 23A involved in the method of forming the semiconductor device, taken along a B-B′ line of FIGS. 2 and 3;

FIG. 24A is a cross sectional elevation view illustrating a semiconductor device in a step involved in a method of forming the semiconductor device, taken along an A-A′ line of FIG. 2;

FIG. 24B is a cross sectional elevation view illustrating a semiconductor device in the step of FIG. 24A involved in the method of forming the semiconductor device, taken along a B-B′ line of FIGS. 2 and 3;

FIG. 25A is a cross sectional elevation view illustrating a semiconductor device in a step, subsequent to the step of FIGS. 24A and 24B, involved in a method of forming the semiconductor device, taken along an A-A′ line of FIG. 2;

FIG. 25B is a cross sectional elevation view illustrating a semiconductor device in the step of FIG. 25A involved in the method of forming the semiconductor device, taken along a B-B′ line of FIGS. 2 and 3;

FIG. 26A is a cross sectional elevation view illustrating a semiconductor device in a step, subsequent to the step of FIGS. 25A and 25B, involved in a method of forming the semiconductor device, taken along an A-A′ line of FIG. 2;

FIG. 26B is a cross sectional elevation view illustrating a semiconductor device in the step of FIG. 26A involved in the method of forming the semiconductor device, taken along a B-B′ line of FIGS. 2 and 3;

FIG. 27A is a cross sectional elevation view illustrating a semiconductor device in a step, subsequent to the step of FIGS. 26A and 26B, involved in a method of forming the semiconductor device, taken along an A-A′ line of FIG. 2;

FIG. 27B is a cross sectional elevation view illustrating a semiconductor device in the step of FIG. 27A involved in the method of forming the semiconductor device, taken along a B-B′ line of FIGS. 2 and 3;

FIG. 28 is a plan view showing an example in which a pattern of a support layer is changed to prevent reduction in strength of a support layer in accordance with the related art; and

FIG. 29 is a schematic sectional view showing batch type wet etching process.

### DETAILED DESCRIPTION OF THE PREFERRED EMBODIMENTS

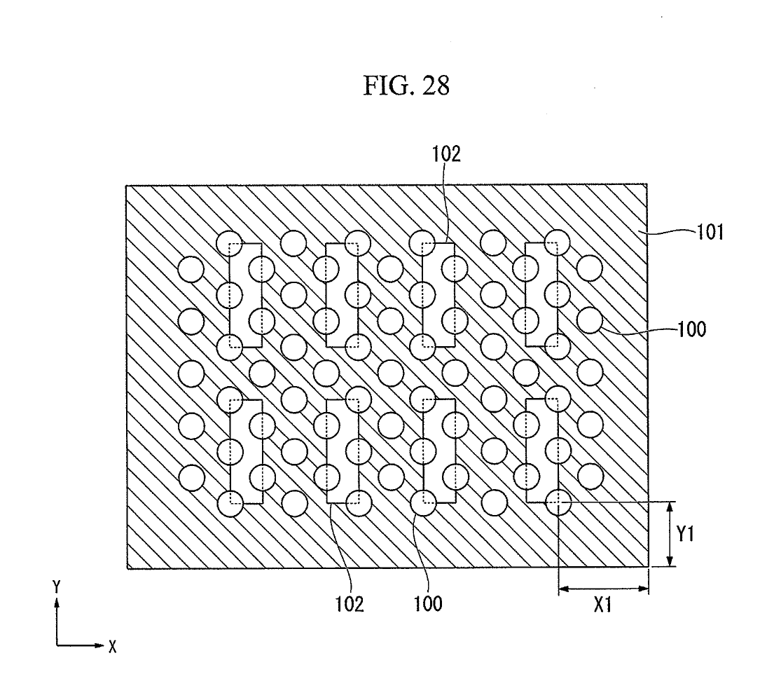

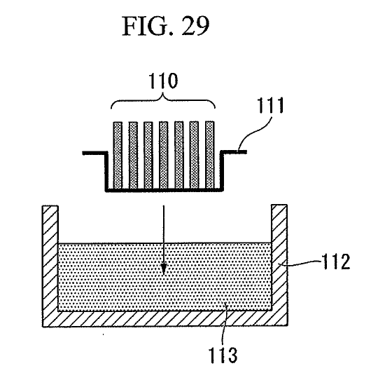

Before describing the present invention, the related art will be explained in detail with reference to FIGS. 28 and 29, in order to facilitate the understanding of the present invention.

There is a pattern in which a support film for supporting a bottom electrode of a capacitor is disposed in a strip shape (line shape) so as to make a connection between adjacent bottom electrodes. Such a pattern has a problem that the holding strength of the support film decreases as the shrinkage progresses. This is because the width of the support film decreases as the shrinkage progresses and accordingly, the strength is reduced. A support film of silicon nitride is etched gradually in a wet etching process. An outer wall portion of a bottom electrode is exposed. A problem may be caused wherein the strength can not be maintained with the support film which has been reduced in size.

FIG. 28 is a plan view showing an example in which a pattern of a support film is changed to prevent reduction in strength of a support film.

Reference numeral 100 denotes a schematic location where a bottom electrode of a capacitor in a memory cell region is disposed. Reference numeral 101 denotes a support film. An opening 102 is provided in the support film 101. Within the opening 102, the bottom electrode 100 and the support film 101 are not in contact with each other. The support film is not disposed in a pattern, in which strip-shaped patterns with fixed widths are combined in a matrix array, as disclosed in Japanese Unexamined Patent Application, First Publication, No. JP-A-2003-297952. As shown in FIG. 28, the openings 102 are provided with predetermined distances therebetween, and a contact state of the support film 101 and the bottom electrode 100 depends on the position where the bottom electrode 100 is disposed. As a result, the width of the support film can increase. The holding strength of the bottom electrode increases.

There is another problem with the support film shown in FIG. 28.

A semiconductor substrate with a support film is subjected to a wet etching process in order to remove an interlayer insulating layer and to expose a side wall of a bottom electrode by. The interlayer insulating layer has a thickness of about 2 μm. The wet etching is performed for a long time period. The wet etching process is performed by dipping a plurality of semiconductor substrates together into a chemical bath, which is called a batch type wet etching process.

FIG. 29 is a schematic sectional view showing batch type wet etching process.

A plurality of semiconductor substrates 110 are currently contained in a carrier 111. The plurality of semiconductor substrates 110 stands perpendicular to the floor surface. A chemical 113, such as hydrofluoric acid (HF), is contained in the chemical bath 112. The carrier 111 does down in the arrow direction so that the plurality of semiconductor substrates 110 is submerged into the chemical 113. In the support film pattern shown in FIG. 28, a corner region is disposed between the most outside opening 102 and the periphery of the support film. The corner region is closest to the corner of the support film 101. The corner region has a width X1 in the X direction and a width Y1 in the Y direction. The corner region is delayed in penetration of an etchant. The corner region is slower in wet-etching rate than other regions, This means that it is possible that the inter-layer insulating film unintentionally resides on the corner region. In order to completely remove the interlayer insulating layer, the wet etching process needs to be carried out for a sufficiently long time. The wet etching process for a sufficiently long time may give damage to the support film.

After a predetermined time has elapsed, the semiconductor substrate 110 is pulled up in the vertical direction from the wet etching chemical bath 112. Then, the semiconductor substrate 110 is then cleared in another bath.

In this case, since the semiconductor substrate 110 is pull up in the vertical direction, the chemical remains in the outer edge (cavity portion formed by etching) of the support film. Before the semiconductor substrate is submerged into the clearing bath, the support film is further etched by the remaining chemical. For this reason, the support film (portion in a cavity where the chemical remains) located on the lower side is easily damaged at the time of the wet etching process. As a result, the strength of the support film is likely to be decreased.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a semiconductor device may include, but is not limited to, a memory cell area; and a peripheral circuit area separated by a groove from the memory cell area; the peripheral circuit area being positioned outside the memory cell area. The memory cell area may include, but is not limited to, a plurality of electrodes that stand; and a first insulating film that support the plurality of electrodes standing. The first insulating film has a plurality of holes through which the plurality of electrodes penetrate. The first insulating film is in contact with at least a part of an outside surface of the electrode. The first insulating film has at least a first opening which is connected to part of the plurality of holes. The first insulating film has at least a second opening which is closer to the groove than any holes of the plurality of holes. The second opening is separated from the plurality of holes.

In some cases, the groove may include four sides which form a rectangle shape. The first insulating film may have a plurality of the second openings aligned along at least one of the four sides of the groove.

In some cases, the second opening may have a rectangle shape.

In some cases, the first and second openings may have rectangle shapes defined by two longer sides and two shorter sides. The longer sides of the first opening extend in a first direction. The longer sides of the second opening extend in a second direction which is different from the first direction.

In some cases, the semiconductor device may further include, but is not limited to, a conductor wall in contact with an inner wall surface of the groove. The conductor wall surrounds the memory cell area. The conductor wall is made of the same conductor as the electrodes. The conductor wall is connected to the first insulating film.

In some cases, the peripheral circuit area may be free of the first insulating film.

In some cases, the semiconductor device may further include, but is not limited to, a silicon nitride film which is in contact with an outer side surface of the bottom of the electrode.

In some cases, the semiconductor device may further include, but is not limited to, a capacitive insulating film on a surface of the electrode, and a second electrode on the capacitive insulating film. The second electrode faces to the first electrode. The capacitive insulating film is disposed between the first and second electrodes.

In one embodiment, a semiconductor device may include, but is not limited to, a memory cell area; and a peripheral circuit area separated by a groove from the memory cell area; the peripheral circuit area being positioned outside the memory cell area. The memory cell area may include, but is not limited to, a plurality of electrodes that stand;

and a first insulating film filling an inner space defined by an inner wall of each of the plurality of electrodes. The first insulating film supports the plurality of electrodes standing. The first insulating film may have at least a first opening that includes part of the plurality of electrodes. The first insulating film may have at least a second opening which is closer to the groove than any electrodes of the plurality of electrodes. The second opening includes none of the plurality of electrodes.

In some cases, the groove may include, but is not limited to, four sides which form a rectangle shape. The first insulating film may have a plurality of the second openings aligned along at least one of the four sides of the groove. In some cases, the second opening may have a rectangle shape.

In some cases, the first and second openings may have rectangle shapes defined by two longer sides and two shorter sides. The longer sides of the first opening extend in a first direction. The longer sides of the second opening extend in a second direction which is different from the first direction.

In some cases, the semiconductor device may further include, but is not limited to, a conductor wall in contact with an inner wall surface of the groove. The conductor wall surrounds the memory cell area. The conductor wall may be made of the same conductor as the electrodes. The conductor wall is connected to the first insulating film.

In some cases, the peripheral circuit area may be free of the first insulating film.

In some cases, the semiconductor device may further include, but is not limited to, a silicon nitride film which is in contact with an outer side surface of the bottom of the electrode.

In some cases, the semiconductor device may further include, but is not limited to, a capacitive insulating film on a surface of the electrode; and a second electrode on the capacitive insulating film, the second electrode facing to the first electrode. The capacitive insulating film is disposed between the first and second electrodes.

In still another embodiment, a semiconductor device may include, but is not limited to, a memory cell area and a peripheral circuit area separated by a groove from the memory cell area. The peripheral circuit area is positioned outside the memory cell area. The memory cell area may include, but is not limited to, a plurality of first electrodes that stand; and a first insulating film being in contact with at least a part of an outside surface of the first electrode. The first insulating film supports the plurality of first electrodes standing. The first insulating film may have at least a first opening that includes part of the plurality of first electrodes. The first insulating film may have at least a second opening which is closer to the groove than any first electrodes of the plurality of first electrodes. The second opening includes none of the plurality of first electrodes. The second opening is separated from the first opening. The memory cell area may include, but is not limited to, a plurality of second electrodes that are connected to the plurality of first electrodes. The plurality of second electrodes is positioned over the plurality of first electrodes. The memory cell area may include, but is not limited to, a second insulating film being in contact with at least a part of an outside surface of the second electrode. The second insulating film supports the plurality of second electrodes standing. The second insulating film may have at least a third opening that includes part of the plurality of second electrodes. The second insulating film may have at least a fourth opening which is closer to the groove than any second electrodes of the plurality of second electrodes. The fourth opening includes none of the plurality of second electrodes. The fourth opening is separated from the third opening.

In some cases, the second and fourth openings may be different in position from each other in plan view.

In some cases, the groove may include, but is not limited to, four sides which form a rectangle shape. The first insulating film may have a plurality of the second openings aligned along at least one of the four sides of the groove. The second insulating film may have a plurality of the fourth openings aligned along the at least one of the four sides of the groove.

In some cases, the semiconductor device may further include, but is not limited to, a capacitive insulating film on surfaces of the first and second electrodes; a third electrode on the capacitive insulating film. The third electrode faces to the first and second electrodes. The capacitive insulating film is disposed between the first and second electrodes and the third electrode.

In yet another embodiment, a method of forming a semiconductor device may include, but is not limited to, the following processes. Contact pads are formed over a semiconductor substrate. A first interlayer insulating film is formed which covers the contact pads. A first insulating film is formed over the first interlayer insulating film. First holes are formed which penetrate the first insulating film and the first interlayer insulating film. The first holes reach the contact pads. First electrodes are formed in contact with inner walls of the first holes and with the contact pads. First and second openings are formed simultaneously in the first insulating film. The first opening is connected to part of the first holes. The second opening is positioned in a peripheral region outside a memory cell area. The second opening is separated from any of the first holes. The first interlayer insulating film is removed to expose outer surfaces of the first electrodes.

In some cases, the semiconductor device may include, but is not limited to, a memory cell area; and a peripheral circuit area separated by a groove from the memory cell area. The peripheral circuit area is positioned outside the memory cell area. The first electrodes are formed in the memory cell area. The method may further include, but is not limited to, forming the groove at the same time of forming the first holes. The groove penetrates the first insulating film and the first interlayer insulating film.

In some cases, the method may further include, but is not limited to, forming a capacitive insulation film which covers the outer surfaces of the first electrodes, after removing the first interlayer insulating film. Second electrodes are formed that faces to the outer surfaces through the capacitive insulation film.

In some cases, the method may further include, but is not limited to, the following processes. The first and second openings are formed. A second interlayer insulating film is formed over the first insulating film. A second insulating film is formed over the second interlayer insulating film. Second holes are formed which penetrate the second insulating film and the second interlayer insulating film. The second holes expose at least part of top surfaces of the first electrodes. Second electrodes are in contact with inner walls of the second holes and with the first electrodes. Third and fourth openings are formed simultaneously in the second insulating film. The third opening is connected to part of the second holes. The fourth opening is positioned in the peripheral region outside the memory cell area. The fourth opening is separated from any of the second holes. The first and second interlayer insulating films are formed to expose outer surfaces of the first and second electrodes.

In some cases, the method may further include, but is not limited to, forming a second groove at the same time of forming the second holes. The second groove penetrates the second insulating film and the second interlayer insulating film.

In some cases, the method may further include, but is not limited to, the following processes. A capacitive insulation film is formed which covers the outer surfaces of the first and second electrodes, after removing the first and second interlayer insulating film. Second electrodes are formed which face to the outer surfaces of the first and second electrodes through the capacitive insulation film.

In some cases, the first interlayer insulating film is removed by a wet etching process which comprises immersing the semiconductor substrate in a vertical direction into an etchant, provided that at least part of the second opening is positioned under the first opening.

Hereinafter, embodiments will be described in detail with reference to the accompanying drawings. In addition, the drawings do not show precise dimensions, thickness of the semiconductor devices.

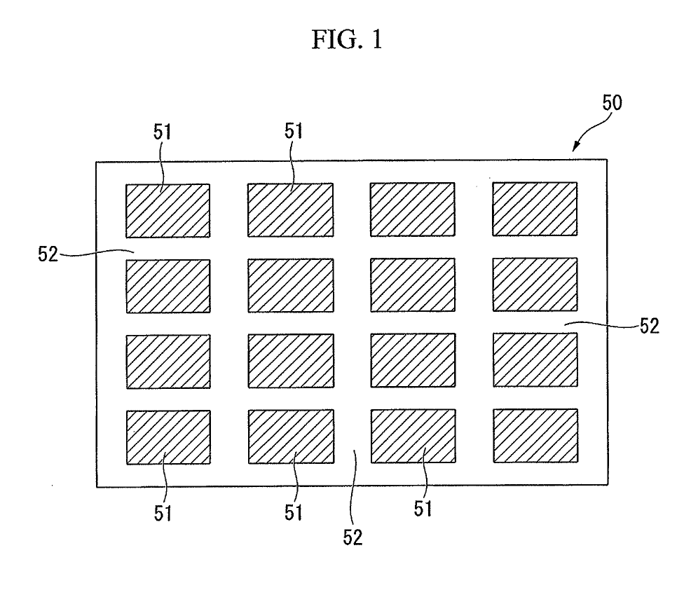

FIG. 1 is a conceptual view showing a DRAM device (semiconductor chip) including a semiconductor device according to the embodiment of the invention.

A DRAM device 50 includes an array of memory cell regions 51 disposed thereon. The DRAM device 50 includes a peripheral circuit region 52 which surrounds the array of memory cell regions 51. The peripheral circuit region 52 includes sense amplifier circuits, word driver circuits, input/output circuits. The array of memory cell regions 51 shown in FIG. 1 is an example, and the number of memory cell regions 51 or the position in the arrangement of the memory cell regions 51 should be not limited to the layout shown in FIG. 1.

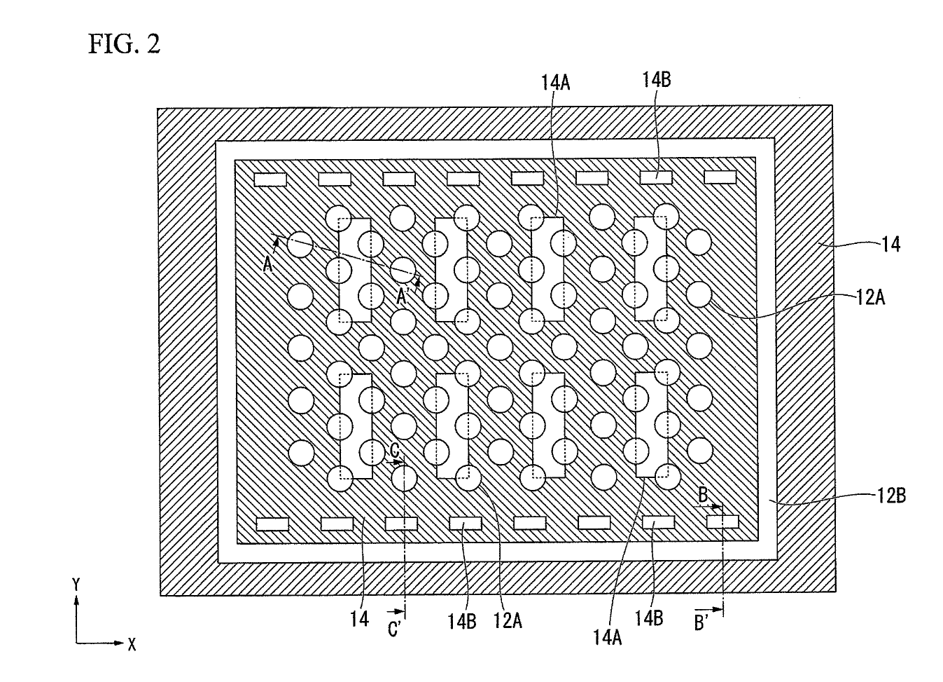

FIG. 2 is a plan view showing a semiconductor device according to the first embodiment of the invention. The semiconductor device includes a memory cell region and a peripheral circuit region. The memory cell region includes a plurality of memory cells. The peripheral circuit region is separated from the memory cell region by a groove 12B in the semiconductor device. The groove 12B extends around the outer edges of the memory cell region. The memory cell region includes the groove 12B and the inner region inside the groove 12B. The peripheral circuit region includes the outer region outside the groove 12B.

Reference numeral 12A denotes the position of a bottom electrode of a capacitor which forms each memory cell. Reference numeral 14 denotes a support film (first insulating layer) disposed to prevent the collapse of a bottom electrode of a capacitor in the course of a manufacturing process, and first openings 14A are provided with predetermined distances therebetween. The first opening 14A is provided such that some capacitor electrodes of a plurality of capacitor electrodes are included thereinside. The support film 14 is provided in a region surrounded by the groove 12B and is also provided in a region located outside the groove 12B. It is preferable that patterning is performed such that the support film 14 ultimately does not remain on the peripheral circuit region 52 after using the function of the support film in the course of a manufacturing process.

A plurality of second openings 14B is provided in a region adjacent to the groove 12B of the support film 14. The first openings 14A and the second openings 14B are simultaneously formed by patterning the support film 14.

In the present embodiment, the groove 12B extends in rectangle in plan view. The groove 12B has four sides. Second openings 14B are aligned along the opposing long sides of the groove 12B. The alignments of the second openings 14B are in the inner region inside the groove 12B.

The arrangement of capacitors shown in FIG. 2 is an example, and the number of capacitors or the position in the arrangement should not be limited to the layout shown in FIG. 2.

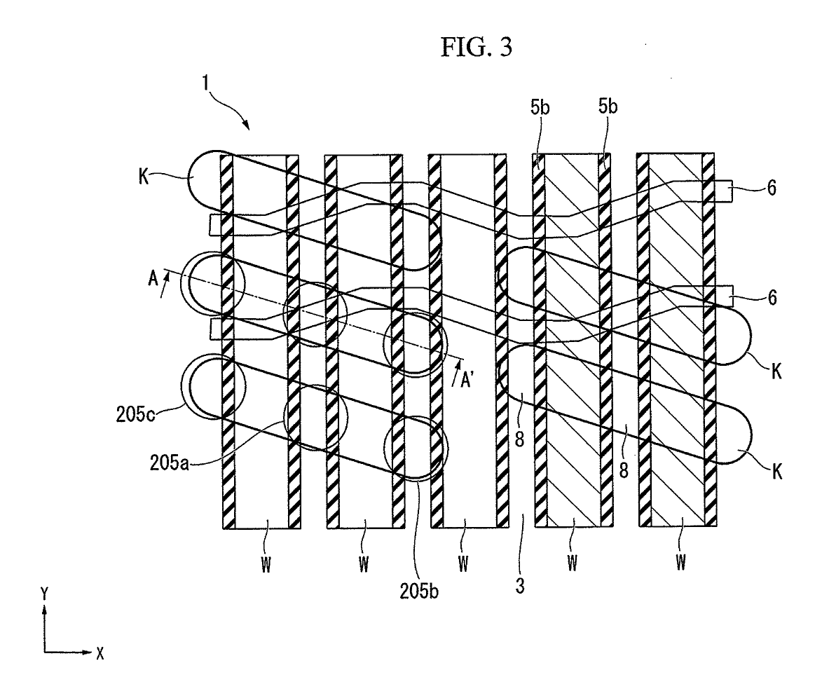

FIG. 3 is a conceptual plan view showing the planar structure of each memory cell in detail. FIG. 3 shows only parts of the elements which form memory cells. On the right side of FIG. 3, a sectional view is shown with a surface, which cuts a sidewall 5b and a gate electrode 5 serving as a word line W, as a reference, which will be described later. A capacitor element is not shown in FIG. 3 and is shown only in the sectional view.

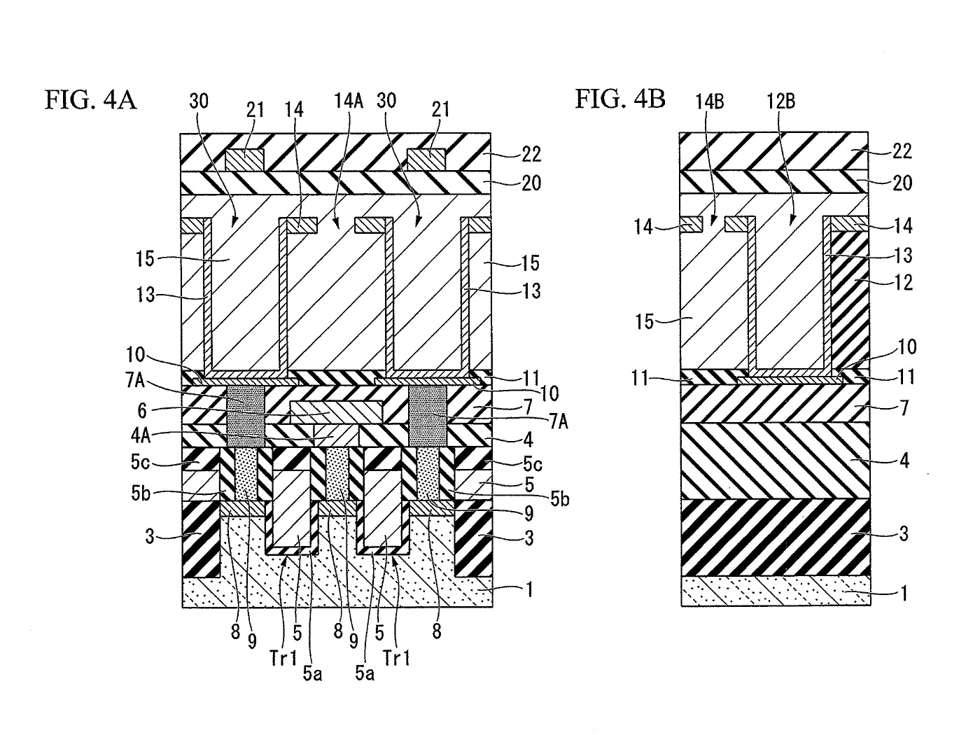

FIG. 4A is a fragmentary cross sectional elevation view taken along the line A-A′ of FIG. 2 and FIG. 3. FIG. 4B is a fragmentary cross sectional elevation view taken along the line B-B′ of FIG. 2.

In FIGS. 4A and 4B, a plurality of capacitor elements 30 is formed on an interlayer insulating layer 7. The interlayer insulating layer 7 embeds a plurality of contact plugs 7A with top portions which are shown on the upper surface of the interlayer insulating layer 7. The capacitor elements 30 are respectively connected to the contact plugs 7A. The support film (first insulating layer) 14 is provided to support the bottom electrode (electrode) 13 of the capacitor element 30. A plurality of holes each penetrate through the support film 14 and each has the bottom electrode 13 as an inner wall. The first opening 14A is formed in the support film 14. The first opening 14A is connected with some of the plurality of holes. The second opening 14B is formed in the support film 14. The second opening 14B is disposed at the position closer to the groove 12B than to any of the plurality of holes. The second opening 14B is not connected with any of the plurality of holes.

As shown in FIG. 4A, each memory cell has a configuration including a MOS transistor Tr1 for a memory cell and the capacitor element (capacitive portion) 30 which is connected to the MOS transistor Tr1 through a plurality of contact plugs 7A.

In FIGS. 3 and 4A, a semiconductor substrate 1 is formed of silicon (Si) containing p-type impurities at a predetermined concentration. An isolation region 3 is formed in this semiconductor substrate 1. The isolation region 3 is formed at a portion other than an active region K by embedding an insulating layer, such as a silicon oxide (SiO₂), on the surface of the semiconductor substrate 1. The isolation region 3 is formed using an STI (Shallow Trench Isolation) method. The isolation region 3 serves to insulate and isolate the adjacent active regions K from each other. In the present embodiment, a cell structure with a 2-bit memory cell in one active region K is shown.

In the present embodiment, like the planar structure shown in FIG. 3, the plurality of active regions K having long and narrow strip shapes is disposed with predetermined distances therebetween so as to be aligned diagonally downward to the right. Diffusion layers are separately formed in both ends and a middle portion of each active region K and serve as source and drain regions of the MOS transistor Tr1. The positions of substrate contact portions 205a, 205b, and 205c are set so as to be disposed directly above the source and drain regions (diffusion layers).

It should not be limited to the arrangement of the active regions K shown in FIG. 3, and the shape of the active region K may be a shape of an active region applied to other general transistors.

In the first direction X in FIG. 3, a bit line 6 is provided to extend in a polygonal line shape or curved shape. The plurality of bit lines 6 are arrayed with predetermined distances therebetween in the second direction Y in FIG. 3. A word line W is disposed which extends in the second direction Yin FIG. 3 and has a linear shape. The plurality of word lines W are arrayed with predetermined distances therebetween in the first direction X in FIG. 3. The word line W is formed so as to include the gate electrode 5 shown in FIG. 4A at a portion where the word line W cross each of the active region K.

In the present embodiment, the MOS transistor Tr1 which has a gate electrode is shown as an example. Instead of the MOS transistor having a gate electrode, it is also possible to use a planar MOS transistor or a MOS transistor in which a channel region is formed in a side surface portion of a groove provided in a semiconductor substrate. Alternatively, a vertical MOS transistor having a pillar shaped channel region may also be used.

As shown in the sectional structure of FIG. 4A, the diffusion layers 8 serve as source and drain regions. The diffusion layers 8 are separately formed in the active region K partitioned by the isolation regions 3 in the semiconductor substrate 1. The gate electrode 5 is formed between the diffusion layers 8. The gate electrode 5 includes multiple layers of a polycrystalline silicon layer and a metal layer. The gate electrode 5 protrudes from the semiconductor substrate 1. In some cases, the polycrystalline silicon layer may be formed by adding impurities, such as phosphorus, at the time of the polycrystalline silicon layer formation process using a CVD (Chemical Vapor Deposition) method. In other cases, n-type or p-type impurities may be introduced using an ion implantation method into the polycrystalline silicon layer, which has been formed free of impurities. High melting point metals, such as tungsten (W), tungsten nitride (WN), and tungsten silicide (WSi), may be used for the metal layer for gate electrodes. As shown in FIG. 4A, a gate insulating layer 5a is formed between the gate electrode 5 and the semiconductor substrate 1. On a side wall of the gate electrode 5, a sidewall 5b is formed by using an insulating layer, such as silicon nitride (Si₃N₄). Also on the gate electrode 5, an insulating layer 5c, such as a silicon nitride, is formed as a protective layer.

The diffusion layer 8 is formed by introducing n-type impurities, for example, phosphorus, into the semiconductor substrate 1. An inter-gate insulating layer is not shown in FIG. 4A. In FIG. 4B, a boundary between the inter-gate insulating layer and an upper first interlayer insulating layer 4 is not shown. The inter-gate insulating layer may be made of silicon oxide, for example. The inter-gate insulating layer is formed by filling silicon oxide into a gap between gate electrodes. A substrate contact plug 9 is formed so as to be in contact with the diffusion layer 8. The substrate contact plugs 9 are disposed at the positions of the substrate contact portions 205a, 205b, and 205c shown in FIG. 3 and are, for example, formed of polycrystalline silicon containing phosphorus. The width of the substrate contact plug 9 in the first direction X is defined by the sidewall 5b provided in an adjacent gate line W. This is a self-alignment structure.

As shown in FIG. 4A, the interlayer insulating layer 4 is formed so as to cover the insulating layer 5c and the substrate contact plug 9 on the gate electrode. A bit line contact plug 4A is formed so as to pass through the interlayer insulating layer 4. The bit line contact plug 4A is disposed at the position of the substrate contact portion 205a. The bit line contact plug 4A is electrically connected to the substrate contact plug 9. The bit line contact plug 4A is formed by laminating tungsten (W) or the like on a barrier layer (TiN/Ti) which has been formed. The barrier layer (TiN/Ti) includes stack of a titanium (Ti) layer and a titanium nitride (TiN) layer. The bit line 6 is connected to the bit line contact plug 4A. The bit line 6 includes stack of a tungsten nitride (WN) layer and a tungsten (W) layer.

The interlayer insulating layer 7 covers the bit line 6. The capacitor contact plug 7A penetrates through the interlayer insulating layer 4 and the interlayer insulating layer 7. The capacitor contact plug 7A is connected to the substrate contact plug 9. The capacitor contact plug 7A is disposed at the positions of the substrate contact portions 205b and 205c.

A capacitor contact pad 10 is disposed on the interlayer insulating layer 7. The capacitor contact pad 10 is electrically connected to the capacitor contact plug 7A. The capacitor contact pad 10 includes stack of a tungsten nitride (WN) layer and a tungsten (W) layer. An interlayer insulating layer 11 (part of a first interlayer insulating layer) may be made of silicon nitride. The interlayer insulating layer 11 covers the capacitor contact pad 10.

The capacitor element 30 extends into the interlayer insulating layer 11. The capacitor element 30 is connected to the capacitor contact pad 10. The capacitor element 30 has such a structure that a capacitor insulating layer (not shown) is interposed between the bottom electrode 13 and the top electrode (another electrode) 15, and that the bottom electrode 13 is connected with the contact plug 7A with the capacitor contact pad 10 interposed therebetween.

As shown in FIG. 4B, the groove 12B, which penetrates through an interlayer insulating layer 12 (part of the first interlayer insulating layer). The groove 12B extends to the middle of the interlayer insulating layer 11. The groove 12B separates a memory cell region from a peripheral circuit region. The groove 12B is provided around the outer edge of the memory cell region. The bottom electrode 13 of the capacitor is formed on the inner wall of the groove 12B. The bottom electrode 13 of the capacitor is formed on an upper end of the groove 12B comes into contact with the support film 14. The bottom electrode 13 is supported by the support film 14. Since the memory cell is surrounded by the groove 128, the chemical of wet etching, which is used in a process of exposing the bottom electrode of the capacitor, is prevented from permeating into the peripheral circuit region in the horizontal direction.

A capacitor element as a storage is not disposed in other region such as peripheral circuit region than the memory cell region of a DRAM device. The interlayer insulating layer 12 may be made of silicon oxide or the like. The interlayer insulating layer 12 is formed on the interlayer insulating layer 11. The support film 14 is disposed so as to cover the upper surface of the peripheral circuit region in the course of manufacturing processes. As a result, the chemical of wet etching, which is used in a process of exposing the bottom electrode of the capacitor, is prevented from permeating into the peripheral circuit region from the upper surface of the substrate.

As shown in FIG. 4A, in the memory cell region, an interlayer insulating layer 20, an upper wiring layer 21 formed of aluminum (Al), copper (Cu), or the like, and a surface protection layer 22 are formed on the capacitor element 30.

### FIRST EMBODIMENT

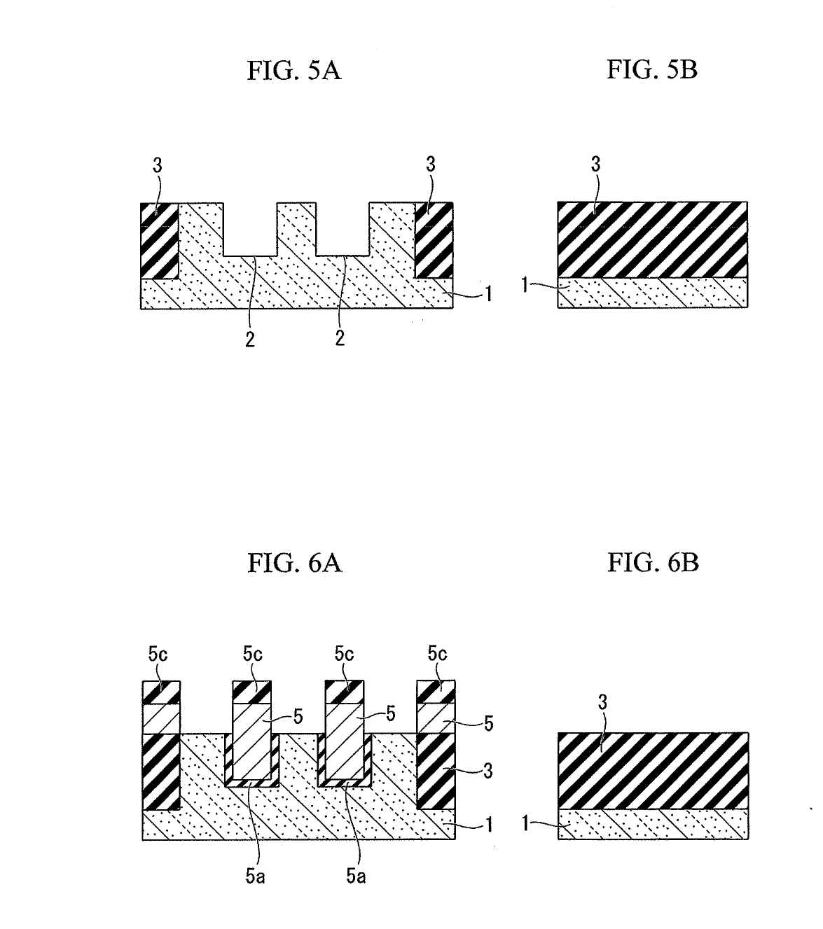

A method of manufacturing a semiconductor device according to a first embodiment of the invention will be described with reference to FIGS. 5A to 14.

FIGS. 5A, 6A, 7A, 8A, 9A, 10A, 11A, 12A, and 13A are fragmentary cross-sectional elevation views taken along the line A-A′ of FIG. 2 or 3 illustrating each memory cell. FIGS. 5B, 6B, 78, 8B, 9B, 10B, 11B, 12B, and 13B are fragmentary cross-sectional elevation views taken along the line B-B′ (FIG. 2) near the outer periphery of the memory cell region.

In the following explanation, unless otherwise noted, a manufacturing process of each memory cell and a manufacturing process near the outer periphery of a memory cell region will be described simultaneously with reference to FIGS. 5A and 5B, 6A and 6B, 7A and 7B, 8A and 8B, 9A and 9B, 10A and 10B, 11A and 11B, 12A and 12B, and 13A and 13B.

Each manufacturing process will be described in detail below.

As shown in FIGS. 5A and 5B, the isolation region 3 is formed at a portion other than the active region K using an STI method. The isolation region 3 isolates the active region K on a main surface of the semiconductor substrate 1 made of p-type silicon. The isolation region 3 includes an insulating layer formed of silicon dioxide (SiO₂). Then, a groove pattern 2 for a gate electrode of the MOS transistor Tr1 is formed. The groove pattern 2 is formed by etching silicon of the semiconductor substrate 1 using a mask (not shown). The mask has been formed by a lithography process.

As shown in FIGS. 6A and 6B, the gate insulating layer 5a with a thickness of about 4 nm is formed in a transistor forming region. The gate insulating layer 5a is formed by oxidizing the surface of the semiconductor substrate 1 using a thermal oxidation method. A stack of a silicon oxide and a silicon nitride or a high-K layer (high dielectric layer) may be used as the gate insulating layer.

In some cases, a polycrystalline silicon layer containing n-type impurities is deposited on the gate insulating layer 5a by a CVD method using monosilane (SiH₄) and phosphine (PH₃). In this case, the polycrystalline silicon layer has such a thickness as to completely fill the inside of the groove pattern 2 for a gate electrode. In other cases, an impurity-free polycrystalline silicon layer free of impurities may be formed before n-type or p-type impurities may be introduced into the impurity-free polycrystalline silicon layer using an ion implantation method. Then, a high melting point metal, such as tungsten silicide, tungsten nitride, or tungsten, is deposited using a sputtering method. The high melting point metal layer is formed on the polycrystalline silicon layer. The high melting point metal layer has a thickness of about 50 nm. The polycrystalline silicon layer and the metal layer are formed for the gate electrode 5 through a process to be described later.

On the metal layer which forms the gate electrode 5, the insulating layer Sc made of silicon nitride is deposited in a thickness of about 70 nm by a plasma CVD method using monosilane and ammonia (NH₃) as source gases. A photoresist film (not shown) is applied on the insulating layer 5c. A photoresist pattern for formation of the gate electrode 5 is formed by a photolithography method using a mask for formation of the gate electrode 5. The insulating layer 5c is etched by anisotropic etching using the photoresist pattern as a mask. After removing the photoresist pattern, the metal layer and the polycrystalline silicon layer are etched using the insulating layer 5c as a hard mask. As a result, the gate electrode 5 is formed. The gate electrode 5 functions as the word line W (FIG. 3).

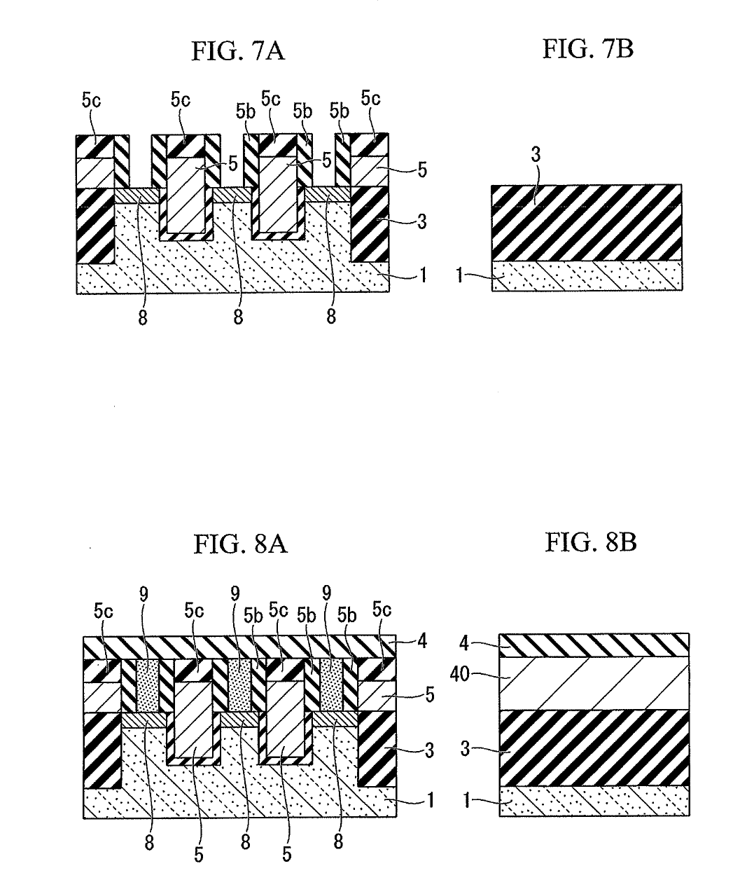

As shown in FIGS. 7A and 7B, the diffusion layer 8 is formed in an active region, which is not covered by the gate electrode 5, by implanting phosphorus ions as n-type impurities.

The sidewall 5b is formed on the side wall of the gate electrode 5 by depositing a silicon nitride layer on the entire surface in a thickness of about 20 to 50 nm using a CVD method and then performing an etch-back process.

As shown in FIGS. 8A and 8B, an inter-gate insulating layer 40 (not shown in FIG. 8A) made of silicon oxide, for example, is formed using the CVD method. The inter-gate insulating layer 40 covers the insulating layer 5c on the gate electrode and the insulating layer 5b on the side surface. The surface of the inter-gate insulating layer 40 is polished by using a CMP (Chemical Mechanical Polishing) method in order to flatten the uneven surface of the inter-gate insulating layer 40. The unevenness was caused by the gate electrode 5. The surface polishing process is terminated when the upper surface of the insulating layer 5c on the gate electrode is exposed. Then, the substrate contact plug 9 is formed.

An etching process is first performed using a photoresist pattern as a mask such that openings are formed at the positions of the substrate contact portions 205a, 205b, and 205c in FIG. 3. As a result, the inter-gate insulating layer formed previously is removed and the surface of the semiconductor substrate 1 is exposed. An opening may be formed between the gate electrodes 5 by self-alignment using the insulating layers 5b and 5c made of silicon nitride. Then, a polycrystalline silicon layer containing phosphorus is deposited by the CVD method. The polycrystalline silicon layer is then polished by the CMP (Chemical Mechanical Polishing) method to thereby remove the polycrystalline silicon layer over the insulating layer 5c. This is the substrate contact plug 9 which fills in the opening.

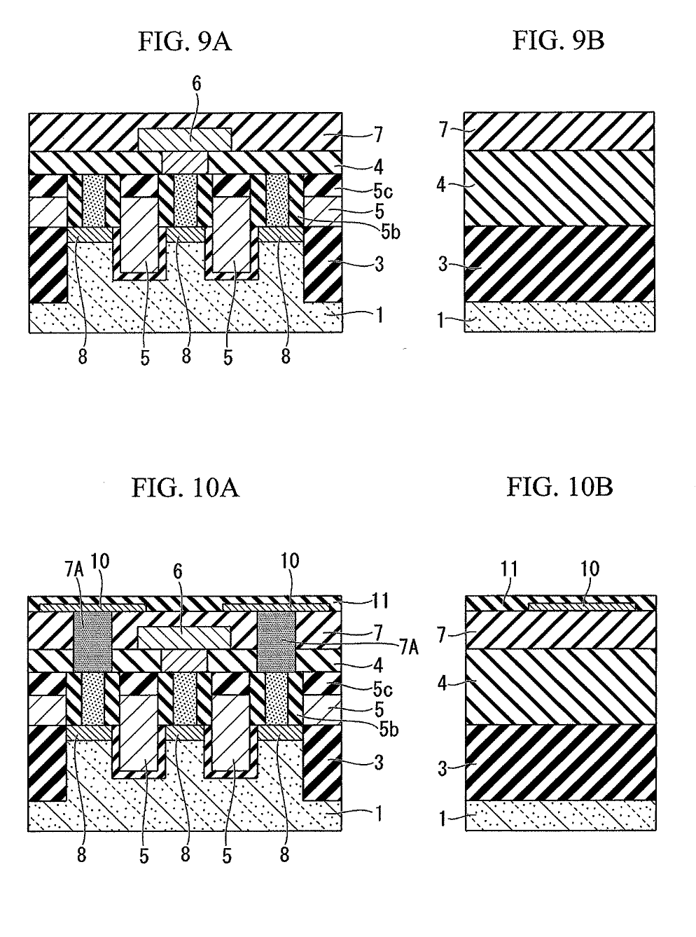

The first interlayer insulating layer 4 made of silicon oxide is formed using the CVD method. The first interlayer insulating layer 4 has a thickness of about 600 nm, for example. The first interlayer insulating layer 4 covers the insulating layer 5c and the substrate contact plug 9 on the gate electrode. Then, the surface of the first interlayer insulating layer 4 is flattened using the CMP method. The CMP process is continued until the thickness of the first interlayer insulating layer 4 reaches about 300 nm, for example. In FIGS. 9B, 10B, 11B, 12B, and 13B, a boundary of the inter-gate insulating layer 40 and the first interlayer insulating layer 4 is not shown. The integrated first interlayer insulating layer 4 is shown.

As shown in FIGS. 9A and 9B, an opening (contact hole) is formed at the position of the substrate contact portion 205a, which is shown in FIG. 3, in the interlayer insulating layer 4. The surface of the substrate contact plug 9 is exposed. The bit line contact plug 4A is formed by depositing tungsten (W) on a barrier layer. The bit line contact plug 4A includes a stack of a TiN layer and a Ti layer. The opening is filled by the layer and then the layer is polished using the CMP method. The bit line 6 is formed. The bit line 6 includes a stack of a tungsten nitride layer and a tungsten layer. The bit line 6 is connected to the bit line contact plug 4A. The interlayer insulating layer (lower interlayer insulating layer) 7 may be made of silicon oxide, for example. The interlayer insulating layer (lower interlayer insulating layer) 7 covers the bit line 6.

As shown in FIGS. 10A and 10B, openings (contact holes) are formed at the positions of the substrate contact portions 205b and 205c in FIG. 3. The openings (contact holes) penetrate through the interlayer insulating layer 4 and the interlayer insulating layer 7. The surface of the substrate contact plug 9 is exposed. The capacitor contact plug 7A is formed by depositing a layer of tungsten (W) on the barrier layer such as TiN/Ti. The opening is filled by the capacitor contact plug 7A. The capacitor contact plug 7A is polished by using the CMP method.

The capacitor contact pad 10 is formed on the interlayer insulating layer 7. The capacitor contact pad 10 includes a stack of a tungsten nitride layer and a tungsten layer. The capacitor contact pad 10 is electrically connected to the capacitor contact plug 7A. The capacitor contact pad 10 is sized larger than a bottom portion of a bottom electrode of a capacitor element which will be formed later. As shown in FIG. 10B, the capacitor contact pad 10 is also disposed near the outer periphery of the memory cell region. Then, the interlayer insulating layer 11 (part of the first interlayer insulating layer) is formed. The interlayer insulating layer 11 may be made of silicon nitride. The interlayer insulating layer 11 has a thickness of 60 nm, for example. The interlayer insulating layer 11 covers the capacitor contact pad 10.

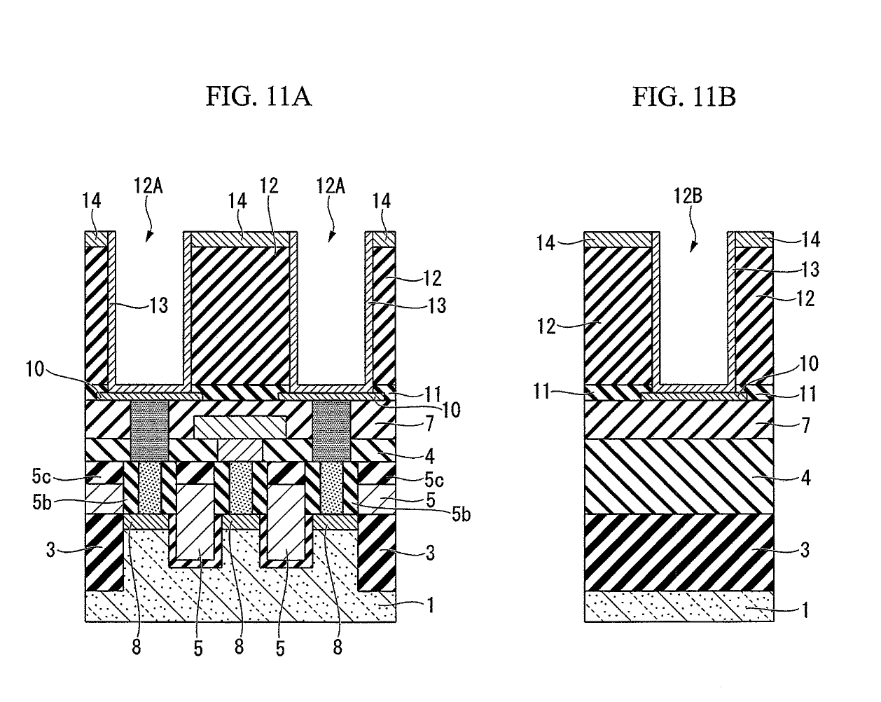

As shown in FIGS. 11A and 11B, the interlayer insulating layer 12 (part of the first interlayer insulating layer) is formed. The interlayer insulating layer 12 has a thickness of 2 μm, for example. The interlayer insulating layer 12 may be made of silicon oxide or the like. The support film (first insulating layer) 14 is deposited on the interlayer insulating layer 12. The support film (first insulating layer) 14 has a thickness of about 100 nm. The support film (first insulating layer) 14 may be made of silicon nitride. It is not necessary to deposit the support film (first insulating layer) on the peripheral circuit region.

Thereafter, an anisotropic dry etching process is carried out. The surface of the capacitor contact pad 10 is exposed by forming a hole 12A at the position, where each of a plurality of capacitor elements is formed. At the same time, the surface of the capacitor contact pad 10 is exposed by forming the groove 12B around the outer edge in the memory cell region as shown in FIG. 11B. The wall surface surrounding the memory cell region is formed by the same conductor as the bottom electrode 13 so as to be in contact with the inner wall of the groove 12B. The support film (first insulating layer) 14 and its wall surface provided in the groove 12B are connected to each other.

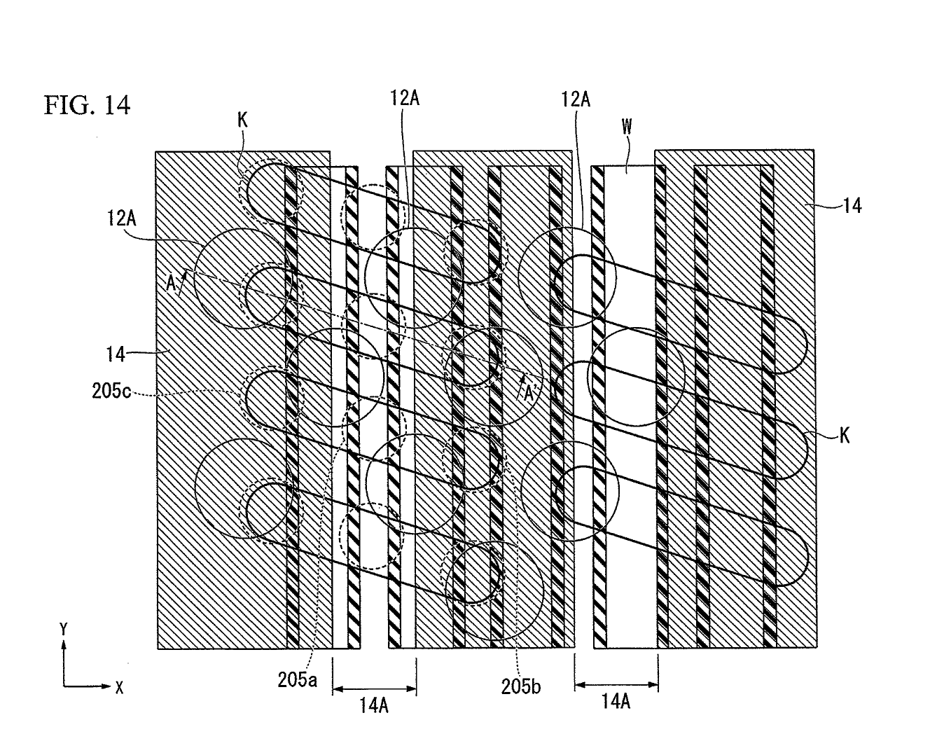

FIG. 14 is a plan view showing arrays of capacitor elements. A bottom electrode of a capacitor element is formed at the position of the hole 12A. In FIG. 14, the capacitor contact pad and the bit line are not shown. The capacitor contact pad is disposed so as to connect the hole 12A (bottom portion of the bottom electrode) with the upper surface of the capacitor contact plug 7A.

After forming the hole 12A and the groove 12B, the bottom electrode (first electrode) 13 of the capacitor element is formed. A titanium nitride film is deposited. The titanium nitride film has such a thickness that the hole 12A and the groove 12B are not completely filled. The titanium nitride film over the interlayer insulating layer 12 is removed by a dry etching process or the CMP method. In this case, a photoresist film, a silicon oxide, or the like may fill the opening in order to protect the bottom electrode in the hole 12A and the groove 12B. If a layer for internal protection is formed in the hole 12A and the groove 12B, then the layer which has protected the insides of the hole 12A and the groove 12B is also removed before the subsequent wet etching process. If the silicon oxide film fills the hole 12A and the groove 12B, then the film in the hole 12A and the groove 12B may be removed before the subsequent wet etching process. As a material for the bottom electrode, a metal layer (for example, ruthenium) other than the titanium nitride may also be used.

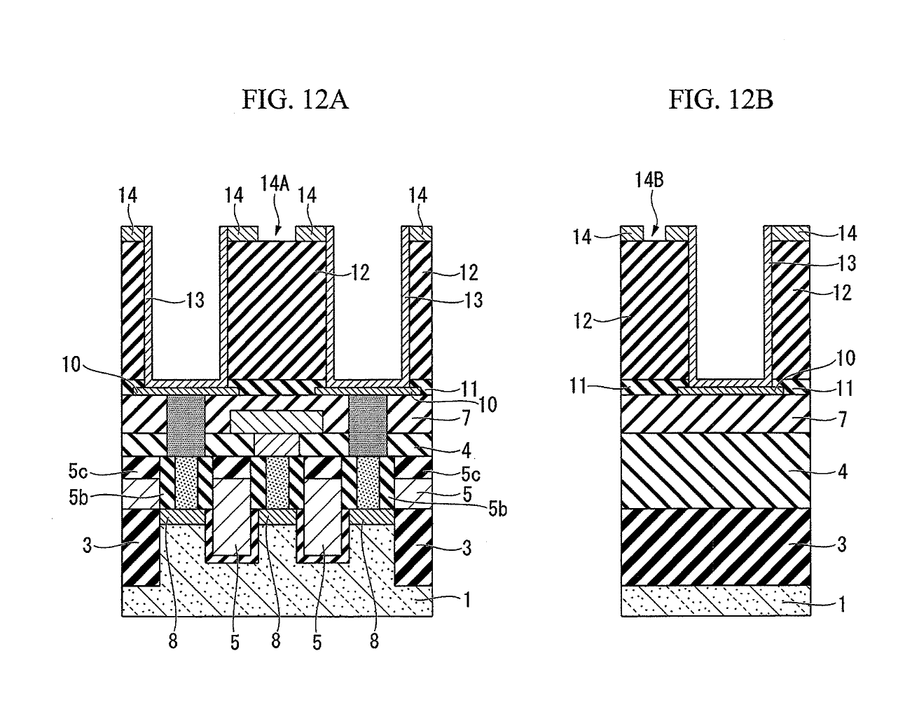

As shown in FIGS. 12A and 12B, the support film 14 is patterned to form the first opening 14A and the second opening 14B. As shown in FIGS. 2 and 14, the first openings 14A are regularly disposed at positions partially overlapping the holes 12A. The first openings 14A are distanced at a predetermined distance. The first openings 14A are connected with the holes 12A. The pattern on a photo mask for forming the first opening 14A is shaped in rectangle. The support film 14A has not existed within the hole 12A. The support film 14 remains in a shape which is defined by the outer periphery (outer periphery of the bottom electrode 13) of the hole 12A. The support film 14 has no portion overlapping the hole 12A. Each bottom electrode may be in contact with the support film at least along a part of the outer periphery. A contact length is defined to be the length of a contact portion along the outer periphery of the bottom electrode. The contact portion is between the bottom electrode and the support film. Different capacitors may have those own contact lengths different from each other. A bottom electrode may be provided together. The outer periphery of the bottom electrode is completely surrounded by the support film 14.

The second openings 14B are formed by disposing a plurality of rectangular patterns with predetermined distances therebetween in regions adjacent to the grooves 12B. The second openings 14B are aligned parallel to the grooves 12B. The second opening 14B may be disposed separately from the positions where the first opening 14A and the hole 12A for a bottom electrode of a capacitor are disposed. The arrangement of the first opening 14A and the second opening 14B shown in FIG. 2 is an example. The shape and the position may be changed. The support film 14 is in contact with an outer wall (wall surface) of the bottom electrode 13. The outer wall (wall surface) is closer to the memory cell region provided in the groove 12B.

At this stage, an opening has not yet been provided in the support film 14 in the peripheral circuit region. Accordingly, the entire upper surface of the interlayer insulating layer 12 in the peripheral circuit region is covered with the support film 14.

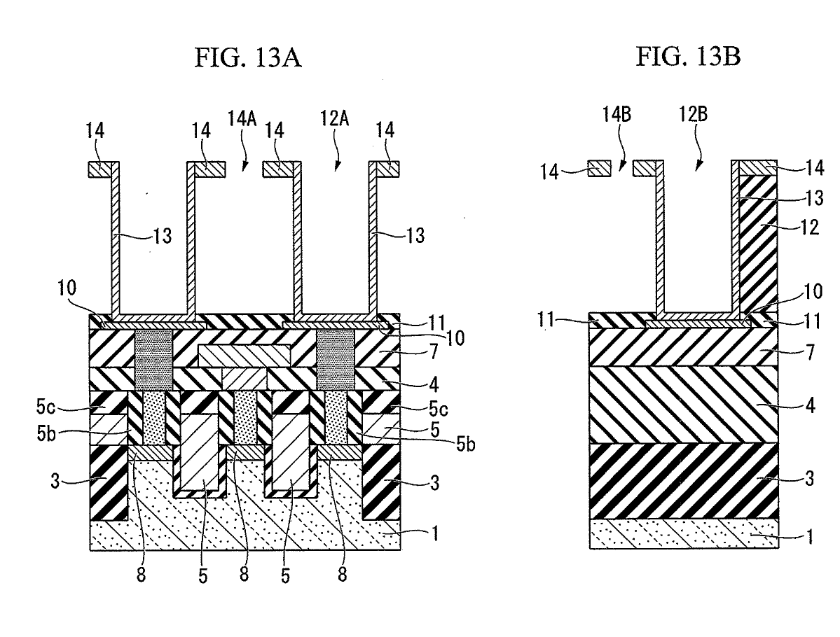

As shown in FIGS. 13A and 13B, the outer wall of the bottom electrode 13 is exposed by performing a wet etching process using hydrofluoric acid (HF) to remove the fourth interlayer insulating layer 12 in the memory cell region.

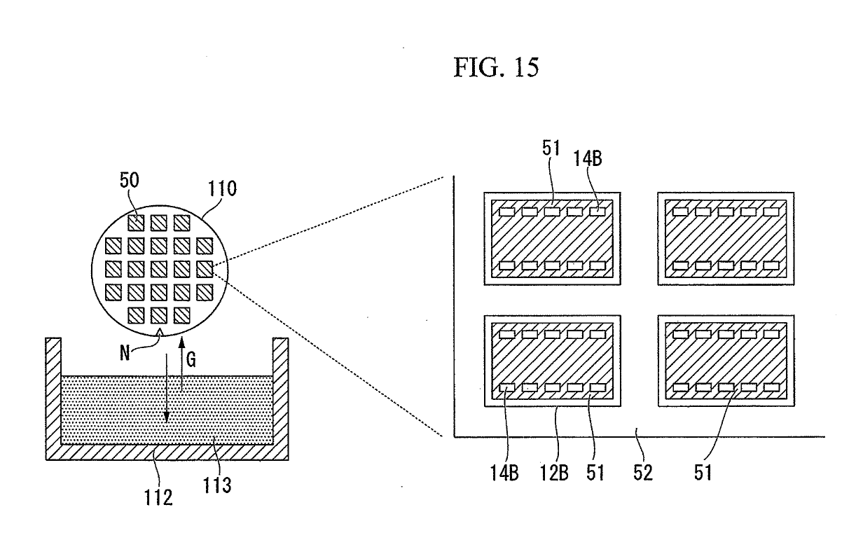

FIG. 15 shows an example of the arrangement relationship between a semiconductor substrate and a chemical bath 112 for a wet etching process. Reference numeral 110 denotes a semiconductor wafer (the entirety of the semiconductor substrate), and a plurality of DRAM devices (chips) 50 are disposed on the surface. A hydrofluoric acid 113 with a predetermined concentration is contained in the chemical bath 112 for a wet etching process.

The semiconductor wafer 110 is moved in a direction indicated by an arrow G (direction perpendicular to the floor surface). The semiconductor wafer 110 is immersed into the chemical bath 112 or taken out of the chemical bath 112. The arrangement of the second opening 14B and the groove 12B provided in the support film of one DRAM device is shown on the right side in FIG. 15. In this example, the second openings 14B are disposed to extend linearly in a direction approximately perpendicular to the movement direction G in which the semiconductor wafer 110 is moved. The semiconductor wafer 110 has a notch N on the outer periphery thereof. An alignment process is carried out by detecting the position of the notch N while rotating the semiconductor wafer. The direction in which the second openings 14B extends can be matched to the direction (direction approximately parallel to the floor surface) approximately perpendicular to the movement direction G. The alignment process is made immediately before performing wet etching. However, it is not necessary to precisely perform the alignment.

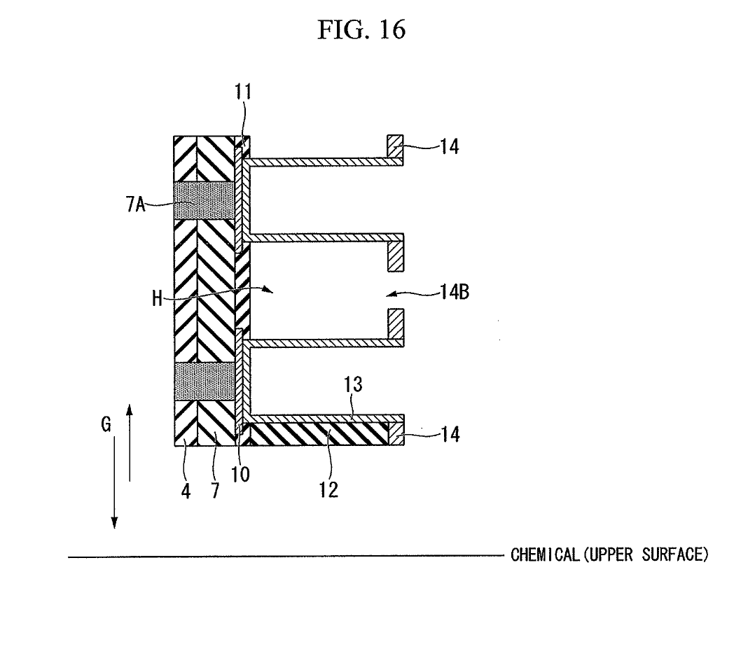

FIG. 16 shows a sectional view taken along the line C-C′ of FIG. 2 in a state where the wet etching process is terminated and the semiconductor wafer 110 is picked up from the chemical bath 112. In FIG. 16, portions lower than first interlayer insulating layer 4 are not shown. In the memory cell region adjacent to the groove 12B, a cavity H is formed by removing the interlayer insulating layer 12. It becomes possible to efficiently discharge the chemical held in the cavity H through the second opening 14B by providing the second opening 14B in the support film 14.

When putting the semiconductor wafer 110 into the chemical tub, the second opening 14B in the support film 14 allows the chemical to permeate into quickly near the outer periphery of the memory cell region.

The interlayer insulating layer 11 made of silicon nitride performs as a stopper layer against permeation of the chemical during the wet etching process. The interlayer insulating layer 11 prevents the structural elements from being etched by the chemicals or etchant. The structural elements are covered by the interlayer insulating layer 11.

The second opening 14B is provided in the support film 14 to perform more quickly permeation and discharging of the chemical than in the related art. As compared to the related art there can be shortened the time when the semiconductor wafer 110 is exposed to the chemical. As a result, there can be suppressed damage to the support film 14 or the interlayer insulating layer (stopper layer) 11 due to the chemical.

The support film 14, which is deposited on the upper surface of the interlayer insulating layer 12, remains in other region (peripheral circuit region) than the memory cell region. The support film 14 will prevent the chemical from permeating from the upper surface during the wet etching process. The support film which covers the peripheral circuit region is gradually etched by the wet etching process. In the wet etching process, it is possible to avoid that the chemical will permeate into the peripheral circuit region by shortening the time when the support film is exposed to the chemical.

In the etching process, the reduction during in the strength of the support film that supports the bottom electrode can be prevented. The bottom electrode 13 can be firmly held by the support film 14. Collapse of the bottom electrode 13 can be prevented.

A capacitor insulating layer (not shown) is formed to cover the side wall surface of the bottom electrode 13. For the capacitor insulating layer, various insulating materials may be available. For example, there may be available high dielectric layers such as a hafnium oxide (HfO₂), a zirconium oxide (ZrO₂), an aluminum oxide (Al₂O₃), strontium titanate (SrTiO₃), and a stack of layers thereof.

As shown in FIG. 4, a top electrode 15 of the capacitor element is formed of a titanium nitride or the like. The top electrode 15 may also include a polycrystalline silicon layer on the titanium nitride, for example. The capacitor element is formed by interposing the capacitor insulating layer into between the bottom electrode 13 and the top electrode 15.

The top electrode 15 is patterned so that the top electrode 15 remains only in the memory cell region. The top electrode 15 is partially removed in the peripheral circuit region. It is preferable to remove the support film 14, which covers the peripheral circuit region, at the same time as the process of patterning the top electrode 15. This is because the formation of an opening of a contact hole becomes easy when forming a contact plug, which connects the upper wiring layer 21 to a lower wiring layer in the peripheral circuit region.

The interlayer insulating layer 20 may be made of silicon oxide or the like. In the memory cell region, a contact plug (not shown) for applying an electric potential to the top electrode 15 of the capacitor element is formed.

The upper wiring layer 21 is formed of aluminum (Al) or copper (Cu), for example. The DRAM device is completed by forming the surface protection layer 22 with a silicon oxynitride (SiON) or the like.

### Modification to First Embodiment:

The arrangement of second openings provided in the support film of the embodiment is not limited to that shown in FIG. 2. The distance between the second opening 14B and the adjacent groove 12B or the distance between the adjacent second openings 14B should not be limited. These distances may be determined in consideration of the strength of the support film 14.

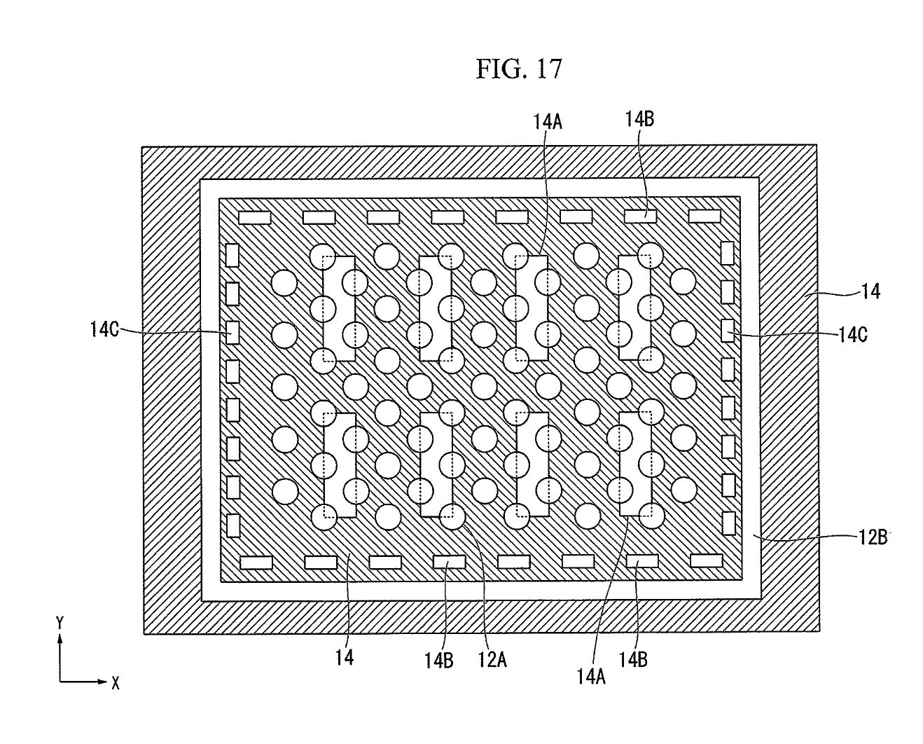

As shown in FIG. 17, the plurality of second openings 14B may be disposed in both directions, X and Y directions, along the outer edge of the memory cell region with a rectangular shape. The plurality of second openings 14B may be disposed along all of the four sides of the groove 12B formed by rectangular grooves on the four sides. The shapes of the openings 14B arrayed in the X and Y directions may be different. The distances between the openings 14B, which are arrayed in the X and Y directions, and the groove 12B may be different. The shape of the opening 14B may be a square, a circle, an ellipse, or a polygon.

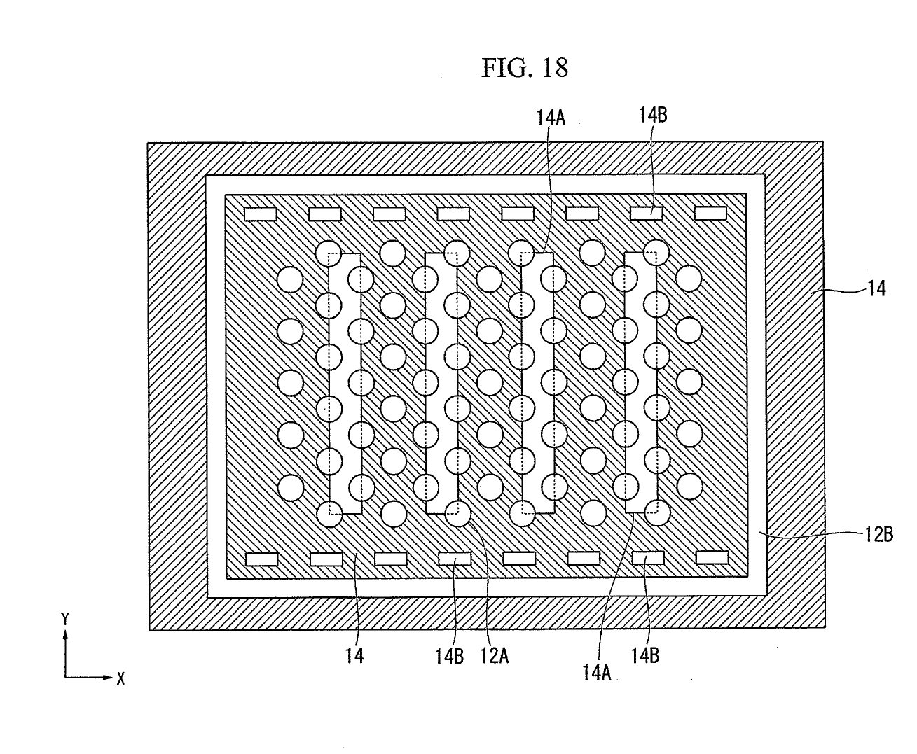

The shape of the first opening 14A provided in a region where the bottom electrode of the capacitor is formed may also be changed. As shown in FIG. 18, the plurality of first openings 14A may be arrayed by providing strip-shaped patterns, which extend in one direction, to be separated from each other by just predetermined distances, such that portions with large widths are provided in the support film 14.

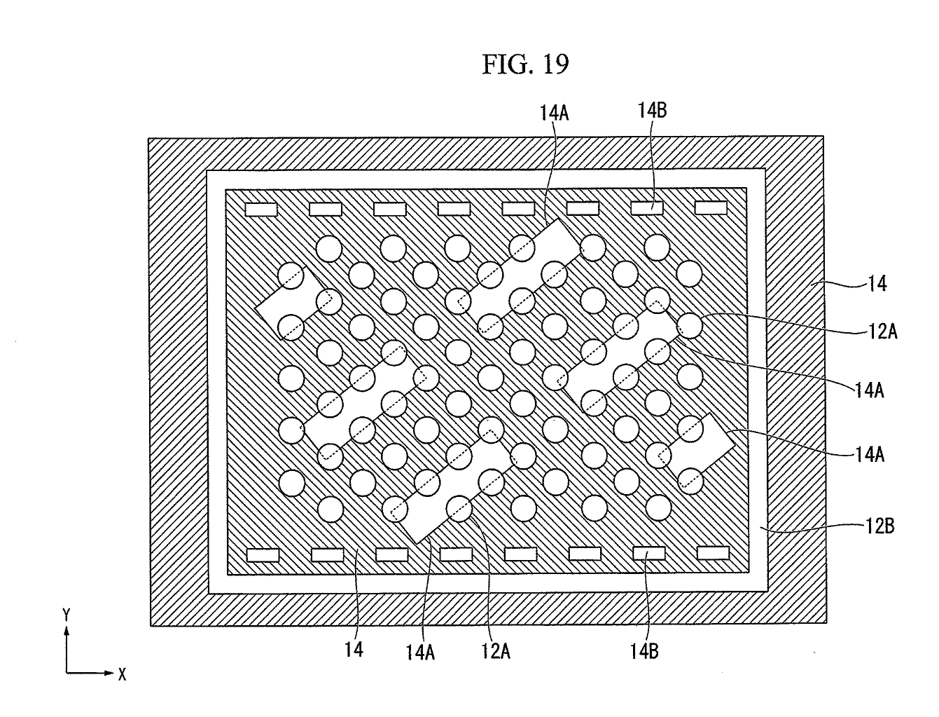

The first openings 14A may extend in an oblique direction, as shown in FIG. 19. The arrangements of the first openings 14A shown in FIGS. 18 and 19 may be combined with the arrangement of the second openings shown in FIG. 17.

The bottom electrode of the capacitor may be of a pillar type in which the hole 12A is completely filled in.

### SECOND EMBODIMENT

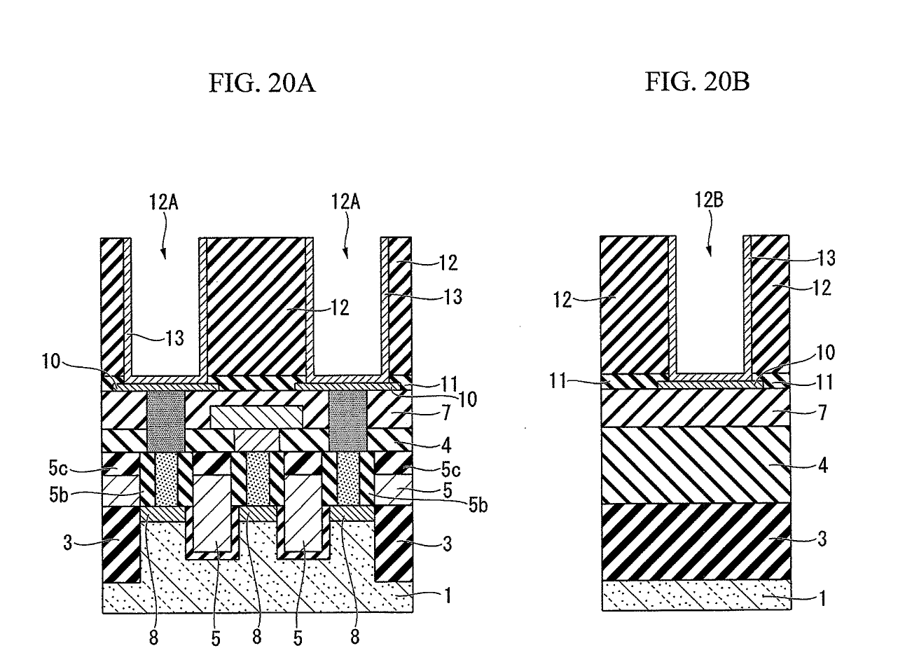

Another embodiment will be described with reference to FIGS. 20A to 23B.

Similar to the embodiment described above, FIGS. 20A, 21A, 22A, and 23A are sectional views taken along the line A-A′ (FIG. 2) of each memory cell. FIGS. 20B, 21B, 22B, and 23B are sectional views taken along the line B-B′ (FIG. 2) in the outer peripheral region of the memory cell region.

In the present embodiment, the same processes are performed as described with reference to FIGS. 5A and 5B to FIGS. 10A and 10B in the first embodiment.

Then, the interlayer insulating layer 12 is deposited using a silicon oxide or the like as shown in FIGS. 20A and 20B, but deposition of a support film is not performed at this stage. Similar to the first embodiment, the hole 12A for a bottom electrode of a capacitor is formed, the groove 12B is formed around the outer edge of the memory cell region, and the bottom electrode 13 is formed in the hole 12A and the groove 12B. The bottom electrode on the interlayer insulating layer 12 is removed, and the bottom electrode is only left in the inner wall of the hole 12A and the groove 12B.

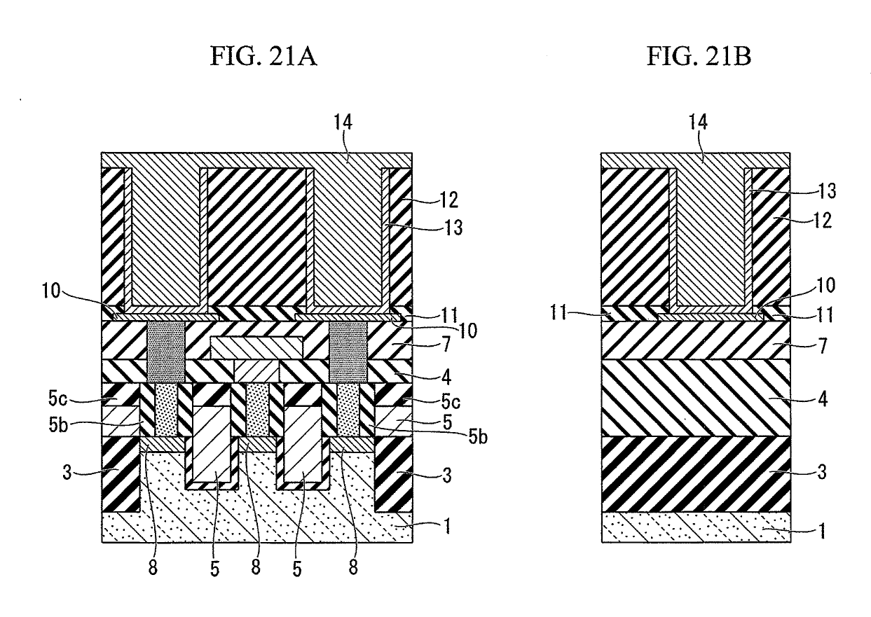

As shown in FIGS. 21A and 21B, the support film 14 is formed by depositing a silicon nitride such that the hole 12A and the groove 12B are filled in and the interlayer insulating layer 12 is covered.

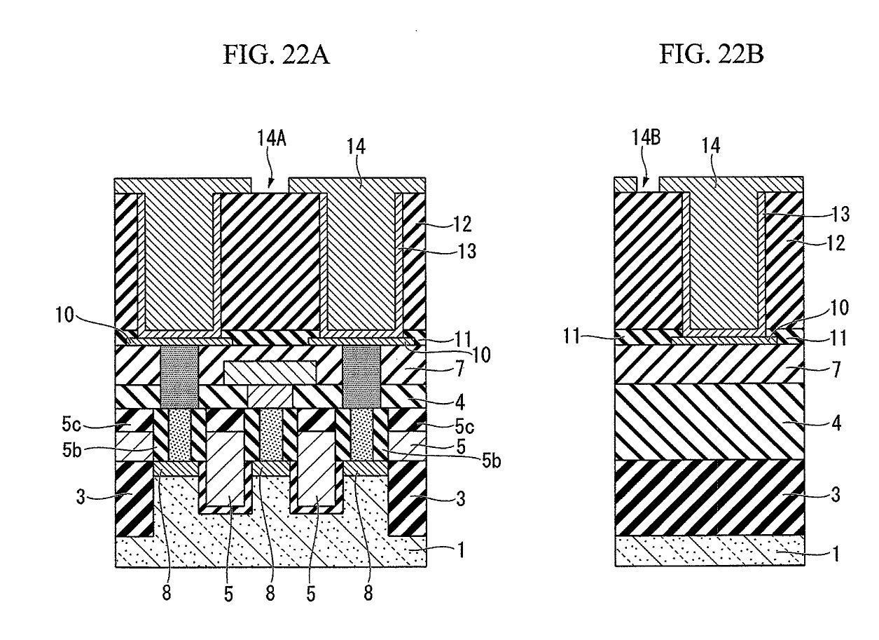

As shown in FIGS. 22A and 22B, dry etching of the support film 14 is performed to form the first opening 14A and the second opening 14B at the same positions as in the first embodiment. The support film 14 is left on the peripheral circuit region.

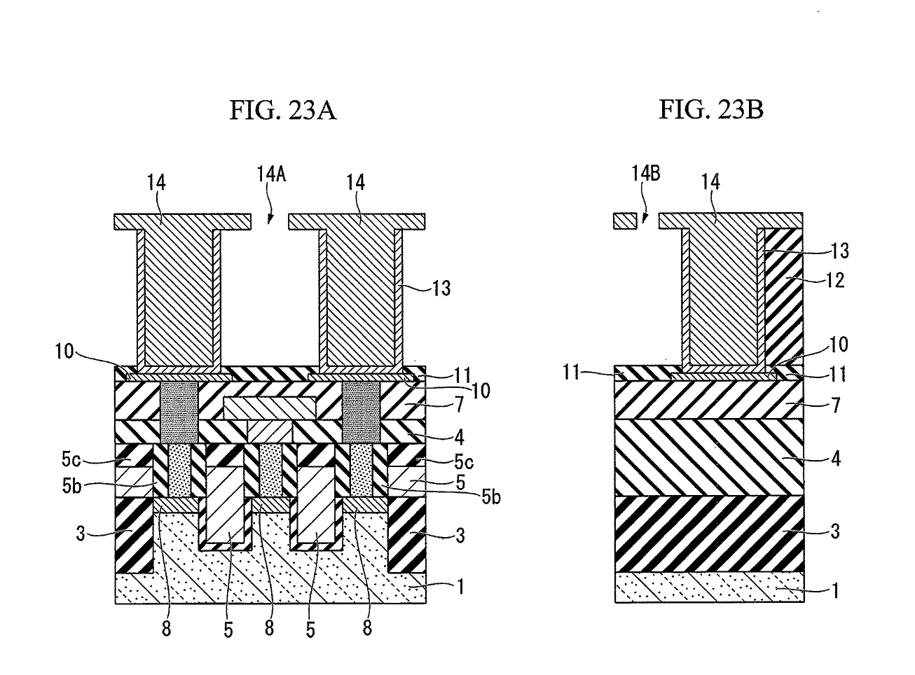

As shown in FIGS. 23A and 23B, the outer wall of the bottom electrode 13 is exposed by performing wet etching to remove the interlayer insulating layer 12 in the memory cell region.

In the present embodiment, since the inside of the bottom electrode 13 is filled in with the support film 14, it becomes possible to hold the bottom electrode 13 more firmly.

In the present embodiment, the permeation of the chemical into the memory cell region and the discharge of the chemical from the memory cell region during the wet etching can be quickly performed by forming the second opening 14B at the position closer to the groove than any of a plurality of holes in the memory cell region. Damage to the support film 14 or the interlayer insulating layer (stopper layer) 11 can be suppressed.

A dielectric layer for a capacitor, a top electrode, an upper interlayer insulating layer, an upper wiring layer, and the like are formed in the same manner as in the first embodiment, thereby completing the DRAM device.

### THIRD EMBODIMENT

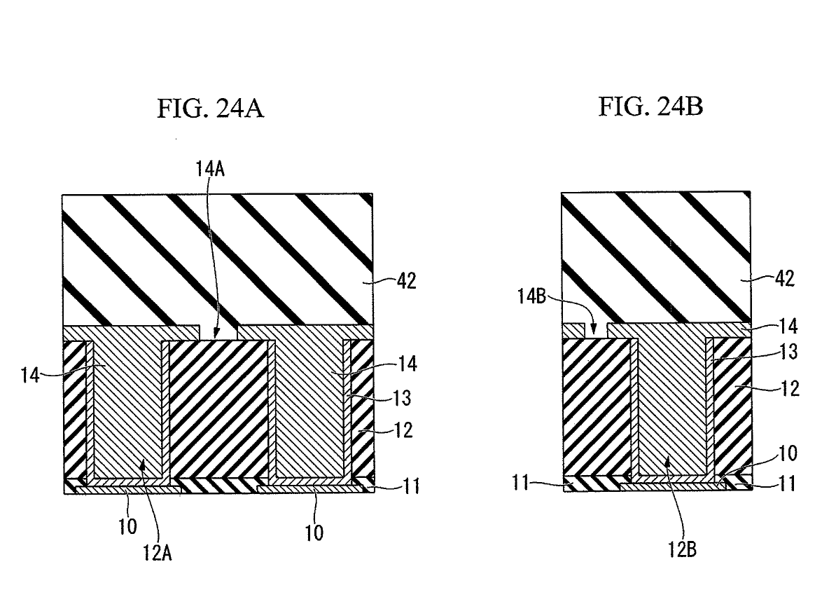

Still another embodiment will be described with reference to FIGS. 24A to 27B in which only structures positioned above the capacitor contact pad 10 in the second embodiment are shown.

FIGS. 24A, 25A, 26A, and 27A are sectional views taken along the line A-A′ (FIG. 2) of each memory cell. FIGS. 24B, 25B, 26B, and 27B are sectional views taken along the line B-B′ (FIG. 2) in the outer peripheral region of the memory cell region.

In the same manner as in the second embodiment, the support film (first insulating layer) 14 including the first opening 14A and the second opening 14B is formed such that the support film (first insulating layer) 14 fills the inside of the bottom electrode (first electrode) 13. As shown in FIGS. 24A and 24B, a second support film (second insulating layer) 42 is formed on the interlayer insulating layer 12 (part of the first interlayer insulating layer) in a thickness of about 1 μm using a silicon oxide or the like.

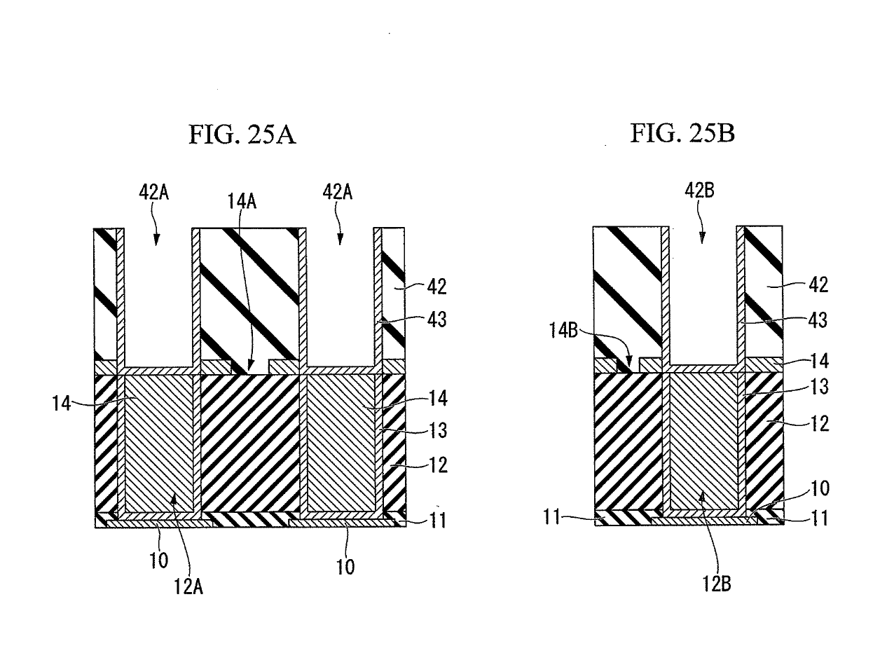

As shown in FIGS. 25A and 25B, a second opening 42A is formed by etching the second support film 42 such that a part of the upper end of the first bottom electrode 13 is exposed and at the same time, the second groove 42B is formed in the outer peripheral portion such that the upper end of the first bottom electrode provided in the groove (first groove) 12B is exposed. A bottom electrode (second electrode) 43 is formed on the inner wall of the second opening 42A and the second groove 42B in the same manner as described previously. The first bottom electrode 13 and the second bottom electrode 43 are electrically connected to each other. The first bottom electrode 13 and the second bottom electrode 43 are partially in contact with each other, and function as one bottom electrode.

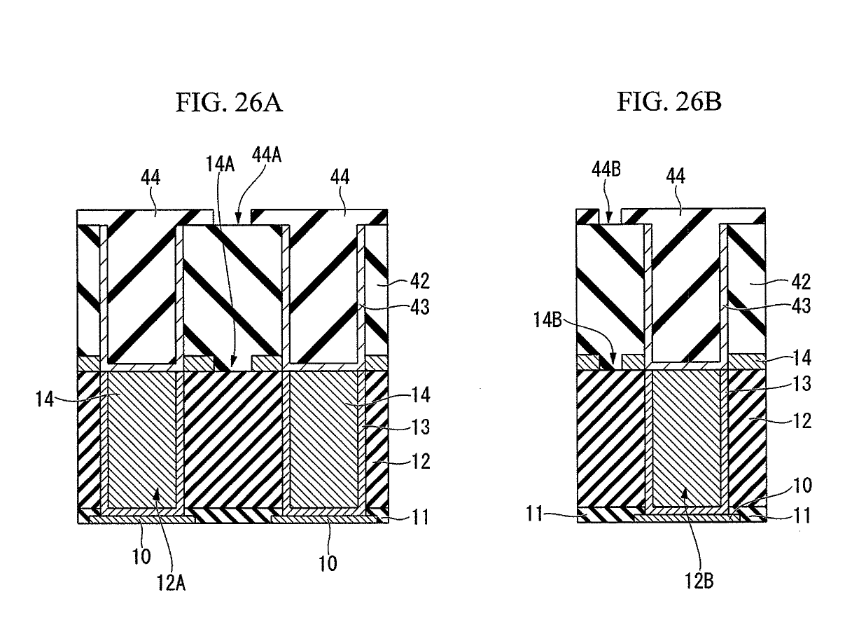

As shown in FIGS. 26A and 26B, the second opening 42A and the second groove 42B are filled in the same manner as described previously. A second support film 44 (second insulating layer) of silicon nitride is deposited. The second support film 44 (second insulating layer) covers the surface of the interlayer insulating layer 42. A third opening 44A and a fourth opening 44B are formed. The positions of the first and third openings 14A and 44A formed in the first and second support films 14 and 44, respectively, may be different in position from each other. The shapes of the first and third openings 14A and 44A may be different from each other. The positions of the second and fourth openings 14B and 44B formed in the first and second support films 14 and 44, respectively, may be different in position from each other. The shapes of the second and fourth openings 14B and 44B may be different from each other.

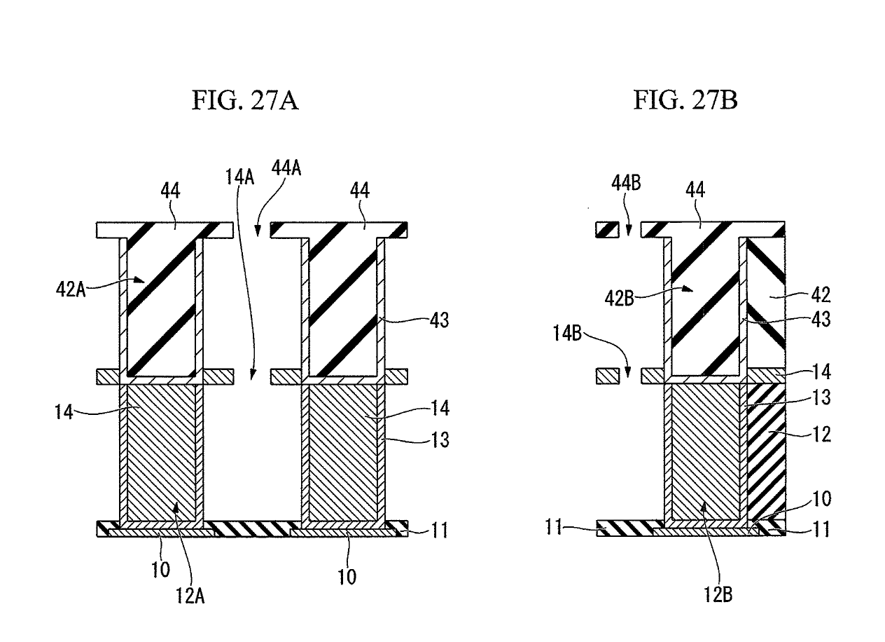

As shown in FIGS. 27A and 27B, outer walls of the first and second electrodes 13 and 43 are exposed by performing a wet etching process using hydrofluoric acid (HF) to remove the interlayer insulating layers 12 and 42 in the memory cell region. A capacitor insulating layer (not shown), a top electrode (not shown), and the like are formed in the same manner as in the first embodiment.

In the present embodiment, since the structure is adopted in which bottom electrodes are laminated twice, a capacitor element with a larger capacitance can be obtained. Since both the first and second bottom electrodes 13 and 43 are supported by the first and second support films 14 and 44, the collapse of a bottom electrode can be prevented even if the height of the bottom electrode increases.

In the outer peripheral region of the memory cell region, the permeation of the chemical to the outside of the memory cell during the wet etching is prevented by the wall including a stacked structure of the first and second grooves 12B and 42B.

In the present embodiment, the permeation of the chemical into the memory cell region and the discharge of the chemical from the memory cell region during the wet etching can be quickly performed by disposing the second and fourth openings 14B and 44B near the outer periphery of the memory cell region. Damage to the first and second support films 14 and 44 or the interlayer insulating layer (stopper layer) 11 can be suppressed.

It is also possible to adopt the structure that bottom electrodes are laminated three times or more in the same manner.

Since the collapse of a bottom electrode is prevented by applying the embodiment, it becomes possible to easily form a capacitor element with a structure in which a plurality of bottom electrodes are laminated. Therefore, a semiconductor device having a capacitor element with a large capacitance can be easily manufactured.

The embodiments may be applied to a method of manufacturing a semiconductor device, which includes a manufacturing process of exposing an outer wall of a bottom electrode of a capacitor using wet etching, and a semiconductor device manufactured by the method.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a memory cell area; and
a peripheral circuit area separated by a groove from the memory cell area the peripheral circuit area being positioned outside the memory cell area; and
the memory cell area comprising:
a plurality of electrodes that stand; and
a first insulating film that support the plurality of electrodes standing,
wherein the first insulating film has a plurality of holes through which the plurality of electrodes penetrate, the first insulating film being in contact with at least a part of an outside surface of the electrode;
the first insulating film has at least a first opening which is connected to part of the plurality of holes; and
the first insulating film has at least a second opening which is closer to the groove than any holes of the plurality of holes, and the second opening is separated from the plurality of holes.

2. The semiconductor device according to claim 1, wherein the groove comprises four sides which form a rectangle shape, and the first insulating film has a plurality of the second openings aligned along at least one of the four sides of the groove.

3. The semiconductor device according to claim 1, wherein the second opening has a rectangle shape.

4. The semiconductor device according to claim 1, wherein the first and second openings have rectangle shapes defined by two longer sides and two shorter sides, the longer sides of the first opening extend in a first direction, and the longer sides of the second opening extend in a second direction which is different from the first direction.

5. The semiconductor device according to claim 1, further comprising:
a conductor wall in contact with an inner wall surface of the groove, the conductor wall surrounding the memory cell area, the conductor wall being made of the same conductor as the electrodes, and the conductor wall being connected to the first insulating film.

6. The semiconductor device according to claim 1, wherein the peripheral circuit area is free of the first insulating film.

7. The semiconductor device according to claim 1, further comprising:
a silicon nitride film which is in contact with an outer side surface of the bottom of the electrode.

8. The semiconductor device according to claim 1, further comprising:
a capacitive insulating film on a surface of the electrode;
a second electrode on the capacitive insulating film, the second electrode facing to the first electrode, the capacitive insulating film being disposed between the first and second electrodes.

9. A semiconductor device comprising:
a memory cell area; and
a peripheral circuit area separated by a groove from the memory cell area; the peripheral circuit area being positioned outside the memory cell area; and
the memory cell area comprising:
a plurality of electrodes that stand; and
a first insulating film filling an inner space defined by an inner wall of each of the plurality of electrodes, the first insulating film supporting the plurality of electrodes standing,
wherein the first insulating film has at least a first opening that includes part of the plurality of electrodes; and
the first insulating film has at least a second opening which is closer to the groove than any electrodes of the plurality of electrodes, and the second opening including none of the plurality of electrodes.

10. The semiconductor device according to claim 9, wherein the groove comprises four sides which form a rectangle shape, and the first insulating film has a plurality of the second openings aligned along at least one of the four sides of the groove.

11. The semiconductor device according to claim 9, wherein the second opening has a rectangle shape.

12. The semiconductor device according to claim 9, wherein the first and second openings have rectangle shapes defined by two longer sides and two shorter sides, the longer sides of the first opening extend in a first direction, and the longer sides of the second opening extend in a second direction which is different from the first direction.

13. The semiconductor device according to claim 9, further comprising:
a conductor wall in contact with an inner wall surface of the groove, the conductor wall surrounding the memory cell area, the conductor wall being made of the same conductor as the electrodes, and the conductor wall being connected to the first insulating film.

14. The semiconductor device according to claim 9, wherein the peripheral circuit area is free of the first insulating film.

15. The semiconductor device according to claim 9, further comprising:
a silicon nitride film which is in contact with an outer side surface of the bottom of the electrode.

16. The semiconductor device according to claim 9, further comprising:
a capacitive insulating film on a surface of the electrode;
a second electrode on the capacitive insulating film, the second electrode facing to the first electrode, the capacitive insulating film being disposed between the first and second electrodes.

17. A semiconductor device comprising:
a memory cell area; and
a peripheral circuit area separated by a groove from the memory cell area; the peripheral circuit area being positioned outside the memory cell area; and
the memory cell area comprising:
a plurality of first electrodes that stand; and
a first insulating film being in contact with at least a part of an outside surface of the first electrode, the first insulating film supporting the plurality of first electrodes standing,
wherein the first insulating film has at least a first opening that includes part of the plurality of first electrodes; and
the first insulating film has at least a second opening which is closer to the groove than any first electrodes of the plurality of first electrodes, and the second opening including none of the plurality of first electrodes, the second opening being separated from the first opening;
a plurality of second electrodes that are connected to the plurality of first electrodes, the plurality of second electrodes being positioned over the plurality of first electrodes; and
a second insulating film being in contact with at least a part of an outside surface of the second electrode, the second insulating film supporting the plurality of second electrodes standing,
wherein the second insulating film has at least a third opening that includes part of the plurality of second electrodes; and
the second insulating film has at least a fourth opening which is closer to the groove than any second electrodes of the plurality of second electrodes, and the fourth opening including none of the plurality of second electrodes, the fourth opening being separated from the third opening.

18. The semiconductor device according to claim 17, wherein the second and fourth openings are different in position from each other in plan view.

19. The semiconductor device according to claim 17, wherein the groove comprises four sides which form a rectangle shape, and the first insulating film has a plurality of the second openings aligned along at least one of the four sides of the groove, and the second insulating film has a plurality of the fourth openings aligned along the at least one of the four sides of the groove.

20. The semiconductor device according to claim 17, further comprising:
a capacitive insulating film on surfaces of the first and second electrodes;
a third electrode on the capacitive insulating film, the third electrode facing to the first and second electrodes, the capacitive insulating film being disposed between the first and second electrodes and the third electrode.
